(19) United States
(12) Patent Application Publication
(10) Pub. No.: US 2018/0211823 A1
(43) Pub. Date: Jul. 26, 2018

(54) APPARATUS FOR VACUUM SPUTTER DEPOSITION AND METHOD THEREFOR

(71) Applicants: Daniel SEVERIN, Alzenau (DE); Thomas GEBELE, Freigericht (DE); Thomas LEIPNITZ, Alzenau (DE); Applied Materials, Inc., Santa Clara, CA (US)

(72) Inventors: Daniel SEVERIN, Alzenau (DE); Thomas GEBELE, Freigericht (DE); Thomas LEIPNITZ, Alzenau (DE)

(21) Appl. No.: 15/746,032

(22) PCT Filed: Aug. 24, 2015
(86) PCT No.: PCT/EP2015/069364

§ 371 Date: Jan. 19, 2018

(51) Int. Cl. H01J 37/32; H01L 21/285; H01J 37/34; H01L 27/12; C23C 14/34; C23C 14/00; C23C 14/08; C23C 14/35

(52) U.S. Cl. CPC H01J 37/32844; H01J 2237/24585; H01L 21/2855; H01J 37/3405; H01L 27/1262; H01J 37/3494; C23C 14/3464; C23C 14/0063; C23C 14/0042; C23C 14/086; C23C 14/352; H01J 2237/332; H01J 2237/0203; H01J 2237/182; H01J 37/32449

(57) ABSTRACT

A apparatus for vacuum sputter deposition is described. The apparatus includes, a vacuum chamber; three or more sputter cathodes within the vacuum chamber for sputtering material on a substrate; a gas distribution system for providing a processing gas including H₂ to the vacuum chamber; a vacuum system for providing a vacuum inside the vacuum chamber; and a safety arrangement for reducing the risk of an oxy-hydrogen explosion, wherein the safety arrangement comprises a dilution gas feeding unit connected to the vacuum system for dilution of the H₂-content of the processing gas.

### TECHNICAL FIELD

The present disclosure relates to an apparatus and a method for coating a substrate in a vacuum process chamber. In particular, the present disclosure relates to an apparatus and a method for forming at least one layer of sputtered material on a substrate for display manufacturing.

### BACKGROUND

In many applications, deposition of thin layers on a substrate, e.g. on a glass substrate is desired. Conventionally, the substrates are coated in different chambers of a coating apparatus. For some applications, the substrates are coated in a vacuum using a vapor deposition technique. Several methods are known for depositing a material on a substrate. For instance, substrates may be coated by a physical vapor deposition (PVD) process, a chemical vapor deposition (CVD) process or a plasma enhanced chemical vapor deposition (PECVD) process, etc. Usually, the process is performed in a process apparatus or process chamber where the substrate to be coated is located.

Electronic devices and particularly opto-electronic devices show a significant reduction in costs over the last years. Further, the pixel density of displays is continuously being increased. For TFT displays, high density TFT integration is desired. However, in spite of the increased number of thin-film transistors (TFT) within a device, an increase in the yield and a reduction in the manufacturing costs are attempted.

Accordingly, there is a continuing demand for providing apparatuses and methods for tuning the TFT display properties during manufacturing, in particular with respect to high quality and low cost.

### SUMMARY

In view of the above, an apparatus for vacuum sputter deposition, a method for reducing the risk of an oxy-hydrogen explosion in a vacuum deposition apparatus and a method of manufacturing at least one layer according to the independent claims are provided. Further advantages, features, aspects and details are apparent from the dependent claims, the description and drawings.

According to one aspect of the present disclosure, an apparatus for vacuum sputter deposition is provided. The apparatus includes a vacuum chamber; three or more sputter cathodes within the vacuum chamber for sputtering material on a substrate; a gas distribution system for providing a processing gas including H₂ to the vacuum chamber; a vacuum system for providing a vacuum inside the vacuum chamber; and a safety arrangement for reducing the risk of an oxy-hydrogen explosion. The safety arrangement includes a dilution gas feeding unit connected to the vacuum system for dilution of the H₂-content of the processing gas.

According to a further aspect of the present disclosure, a method for reducing the risk of an oxy-hydrogen explosion in a vacuum deposition apparatus is provided, wherein during vacuum deposition a processing gas with an H₂-content of at least 2.2% is employed. The method includes feeding a dilution gas to a vacuum system of the vacuum deposition apparatus, and diluting the H₂-content in the vacuum system with a dilution ratio of H₂/dilution gas of at least 1/5.

According to a further aspect of the present disclosure, a method of manufacturing at least one layer is provided. The method includes sputtering a layer from a sputter material containing cathode onto a substrate in a processing gas within a vacuum chamber, wherein the substrate is at rest during sputtering, wherein the processing gas includes H₂; O₂ and an inert gas, wherein the content of H₂ is from 2.2% to 30.0%. Further the method of manufacturing at least one layer includes conducting the method for reducing the risk of an oxy-hydrogen explosion in a vacuum deposition apparatus according to embodiments described herein.

The disclosure is also directed to an apparatus for carrying out the disclosed methods including apparatus parts for performing the methods. The method may be performed by way of hardware components, a computer programmed by appropriate software, by any combination of the two or in any other manner. Furthermore, the disclosure is also directed to operating methods of the described apparatus. The disclosure also includes a method for carrying out every function of the apparatus.

### BRIEF DESCRIPTION OF THE DRAWINGS

So that the manner in which the above recited features of the disclosure described herein can be understood in detail, a more particular description, briefly summarized above, may be had by reference to embodiments. The accompanying drawings relate to embodiments of the disclosure and are described in the following:

FIG. 1 shows a schematic view of an apparatus for vacuum sputter according to embodiments described herein;

FIG. 2 shows a schematic view of an apparatus for vacuum sputter according to embodiments described herein;

FIG. 3 shows a schematic view of an apparatus for vacuum sputter according to embodiments described herein;

FIG. 4A shows a block diagram illustrating a method for reducing the risk of an oxy-hydrogen explosion in a vacuum deposition apparatus according to embodiments as described herein;

FIG. 4B shows a block diagram illustrating a method for reducing the risk of an oxy-hydrogen explosion in a vacuum deposition apparatus according to embodiments as described herein; and

FIG. 5 shows a block diagram illustrating a method of manufacturing at least one layer according to embodiments as described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. In the following, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield a further embodiment. It is intended that the description includes such modifications and variations.

In the present disclosure, the expression “processing gas atmosphere” may be understood as an atmosphere inside a processing chamber, particularly inside a vacuum processing chamber of an apparatus for depositing a layer. The “processing gas atmosphere” may have a volume which is specified by the volume inside the processing chamber.

In the present disclosure, the expression “apparatus for vacuum sputter deposition” may be understood as an apparatus for depositing material on a substrate in a vacuum atmosphere environment. Further, in the present disclosure, a “vacuum chamber” may be understood as a chamber which is configured for establishing a vacuum therein. In the present disclosure, a “vacuum system” may be understood as a system configured for providing a vacuum in deposition chamber, e.g. a vacuum deposition chamber. For example, a “vacuum system” may include at least one vacuum pump for establishing a vacuum in the deposition chamber.

In the present disclosure, the expression “sputter cathode” may be understood as a deposition source for sputtering material on a substrate. A “sputter cathode” may be rotatable cathode with magnet assemblies, as described herein.

In the present disclosure, the expression “gas distribution system” may be understood as a system configured for providing a processing gas to a deposition chamber, e.g. a vacuum chamber. The “gas distribution system” may be configured for controlling the composition of the processing gas in the deposition chamber.

In the present disclosure, the abbreviation “H₂” stands for hydrogen, in particular for gaseous hydrogen. Further, in the present disclosure, the abbreviation “O₂” stands for oxygen, in particular for gaseous oxygen.

In the present disclosure, the expression “safety arrangement” may be understood as an arrangement with which the safety of a deposition apparatus as described herein may be increased, for example by reducing the risk of an oxy-hydrogen explosion.

In the present disclosure, the expression “reducing risk of an oxy-hydrogen explosion in a vacuum deposition apparatus” is to be understood that the risk of an oxy-hydrogen explosion may be reduced or eliminated in any subsystem of the vacuum deposition apparatus, e.g. in the vacuum system, in the gas distribution system, in the processing chamber, in the pumps, in the pump exhaust etc.

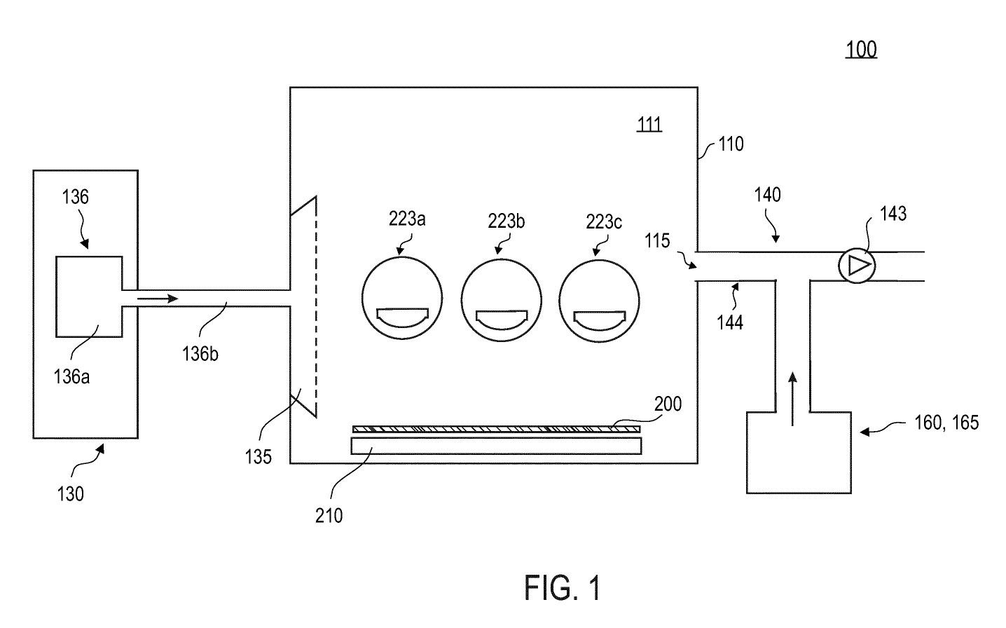

In FIG. 1 a schematic view of an apparatus 100 for vacuum sputter deposition according to embodiments described herein is shown. According to embodiments as described herein, the apparatus includes a vacuum chamber 110; three or more sputter cathodes, e.g. a cathode array including a first sputter cathode 223a, a second sputter cathode 223b, and a third sputter cathode 223c, within the vacuum chamber 110 for sputtering material on a substrate. Further, the apparatus includes a gas distribution system 130 for providing a processing gas including H₂ to the vacuum chamber 110; a vacuum system 140 for providing a vacuum inside the vacuum chamber 110; and a safety arrangement 160 for reducing the risk of an oxy-hydrogen explosion.

According to some embodiments, which may be combined with other embodiments described herein, the apparatus may be configured for static vacuum sputter deposition, i.e. a substrate to be coated is not moved continuously through a deposition zone. Typically, particularly for large area substrate processing it can be distinguished between static deposition and dynamic deposition. A dynamic deposition may be understood as a deposition in an inline process where the substrate moves continuously or quasi-continuously adjacent to the deposition source, e.g. the sputter cathodes.

According to embodiments described herein a static vacuum sputter deposition may be understood as a sputter deposition process in which the plasma can be stabilized prior to deposition of a layer on a substrate. In this regard, it should be noted that the term static deposition process, which is different as compared to dynamic deposition processes, does not exclude any movement of the substrate as would be appreciated by a skilled person. A static deposition process can include one or more of the following aspects. For example, a static deposition process may include a static substrate position during deposition, an oscillating substrate position during deposition, and/or an average substrate position that is essentially constant during deposition. Further, a static deposition process may include, for example, a dithering substrate position during deposition, a wobbling substrate position during deposition, and/or a deposition process for which the cathodes are provided in one chamber, i.e. a predetermined set of cathodes provided in the chamber. Additionally or alternatively, a static deposition process may include, for example, a substrate position wherein the deposition chamber has a sealed atmosphere with respect to neighboring chambers, e.g. by closing valve units separating the chamber from an adjacent chamber, during deposition of the layer. Accordingly, a static deposition process can be understood as a deposition process with a static position, a deposition process with an essentially static position, or a deposition process with a partially static position of the substrate. Accordingly, a static deposition process, as described herein, can be clearly distinguished from a dynamic deposition process without the necessity that the substrate position for the static deposition process is fully without any movement during deposition.

However, it is to be understood that the aspects described herein, particularly the aspects described with respect to the gas distribution system 130, the vacuum system 140 and the safety arrangement 160 of the apparatus for vacuum sputter deposition may also be applied to an apparatus configured for dynamic vacuum sputter deposition, i.e. a substrate to be coated is moved continuously through a deposition zone. Accordingly, the aspects described herein with respect to the gas distribution system 130, the vacuum system 140 and the safety arrangement 160 may also be applied to an apparatus for vacuum sputter deposition having one or more sputter cathodes within the vacuum chamber for sputtering material on a substrate.

Accordingly, according to embodiments which can be combined with other embodiments described herein, an apparatus 100 for vacuum sputter deposition is provided including: a vacuum chamber 110; one or more sputter cathodes within the vacuum chamber 110 for sputtering material on a substrate 200; a gas distribution system 130 for providing a processing gas including H₂ to the vacuum chamber 110; a vacuum system 140 for providing a vacuum inside the vacuum chamber 110; and a safety arrangement 160 for reducing the risk of an oxy-hydrogen explosion. The safety arrangement 160 includes a dilution gas feeding unit 165 connected to the vacuum system 140 for dilution of the H₂-content of the processing gas.

According to embodiments which can be combined with other embodiments described herein, the safety arrangement 160 may include a dilution gas feeding unit 165 connected to the vacuum system 140 for dilution of the H₂-content of the processing gas, as exemplarily shown in FIGS. 1 to 3. Accordingly, an apparatus for vacuum sputter deposition is provided with which a processing gas including a high H₂-content can be used. In particular, by providing an apparatus for vacuum sputter deposition including a safety arrangement as described herein, an apparatus for vacuum sputter deposition is provided which may be operated with a processing gas atmosphere 111 having a content of H₂ from 2.2% to 30.0%. Accordingly, embodiments of the apparatus as described herein provide an apparatus for vacuum sputter deposition in a processing gas atmosphere having a content of H₂ from 2.2% to 30.0% in which the risk of an oxy-hydrogen explosion is reduced or even eliminated.

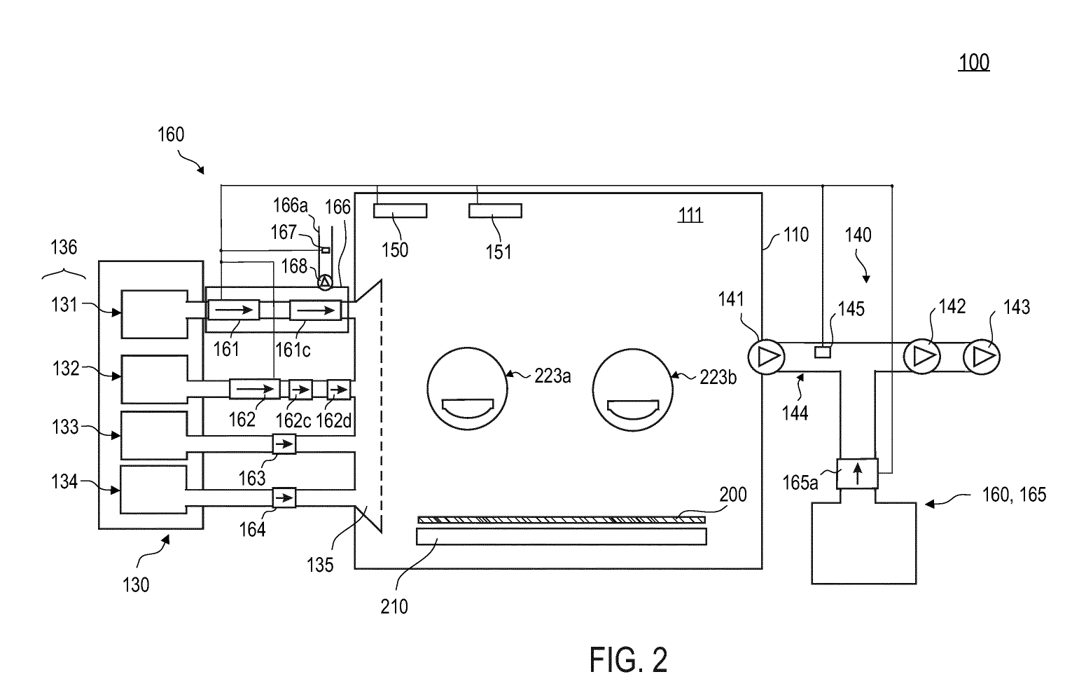

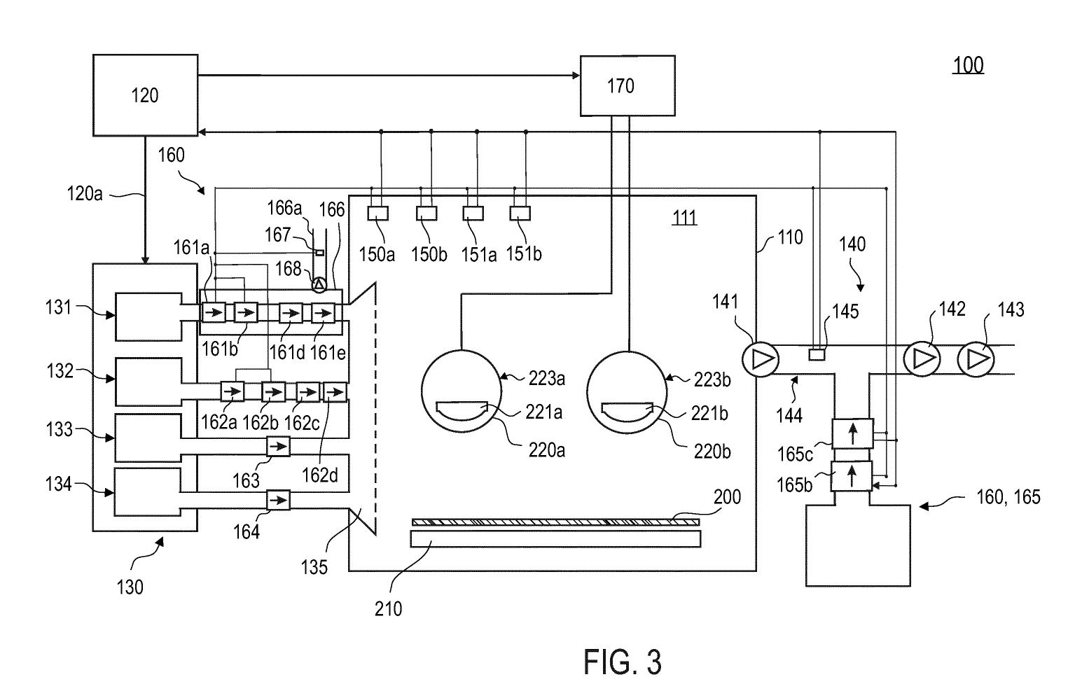

According to embodiments which can be combined with other embodiments described herein, a sputter cathode as described herein may include an indium oxide, particularly indium tin oxide (ITO), containing target. For example, FIG. 3 shows an embodiment including a first indium oxide containing target 220a and a second indium oxide containing target 220b within the vacuum chamber for sputtering a transparent conductive oxide layer. For simplicity, only two sputter cathodes are shown in FIGS. 2 and 3. However, it is to be understood that the aspects of the apparatus according to embodiments of the present disclosure which are described with reference to FIGS. 2 and 3 may also apply to embodiments of the apparatus having three or more sputter cathodes within the vacuum chamber.

According to embodiments which can be combined with other embodiments described herein, an indium tin oxide (ITO) containing target of embodiments as described herein may be an ITO 90/10 containing target. According to embodiments described herein, ITO 90/10 includes an indium oxide (In₂O₃) and a tin oxide (SnO₂) at a ratio of In₂O₃:SnO₂=90:10. Alternatively, an indium tin oxide (ITO) containing target of embodiments as described herein may include an indium oxide (In₂O₃) and a tin oxide (SnO₂) having any ratio of In₂O₃:SnO selected from a range from a first ratio of In₂O₃:SnO₂=85:15 to a second ratio of In₂O₃:SnO₂=98:2.

As exemplarily shown in FIG. 1, according to embodiments which can be combined with other embodiments described herein, the gas distribution system 130 may be connected to the vacuum chamber 110 via a processing gas supply unit 136. The processing gas supply unit 136 may include a processing gas source 136a, e.g. a processing gas tank, which is connected to the vacuum chamber 110 via a processing gas supply pipe 136b. The processing gas may be provided from the processing gas supply unit 136 to the vacuum chamber 110 via a shower head 135.

As exemplarily shown in FIG. 1, according to embodiments which can be combined with other embodiments described herein, the vacuum system 140 may include at least one vacuum pump 143 and a pipe 144 configured for connecting the vacuum pump to be in fluid communication with the vacuum chamber 110, for example via an outlet port 115 of the vacuum chamber 110. The dilution gas feeding unit 165 may be connected to the pipe 144 between the vacuum chamber 110, particularly the outlet port 115 of the vacuum chamber 110, and the vacuum pump 143. According to another example (not shown in the Figures) the dilution gas feeding unit may be connected to a pre-vacuum pump 142 and/or the at least one vacuum pump 143. The vacuum pump 143 may be a rotary vane pump. Accordingly, an apparatus for vacuum sputter deposition is provided in which the processing gas supplied from the vacuum chamber 110 into the vacuum system 140 can be diluted by a dilution gas before being pumped by the vacuum pump 143. Accordingly, the risk of an oxy-hydrogen explosion may be reduced or even eliminated.

As exemplarily shown in FIG. 2, according to embodiments which can be combined with other embodiments described herein, the processing gas supply unit 136 may include one or more separate individual gas supply units, for example one or more separate individual gas supply units selected form the group consisting of: a H₂-supply unit 131, an O₂-supply unit 132, a water vapor supply unit 133 and an inert gas supply unit 134. It is to be understood that the H₂-supply unit 131 is configured for providing H₂ to vacuum chamber 110 for establishing a processing gas atmosphere 111 having a H₂-content as described herein. Accordingly, it is to be understood that the O₂-supply unit 132, the water vapor supply unit 133, and the inert gas supply unit 134 are configured for providing O₂, water vapor and inert gas, respectively, to the vacuum chamber 110 for establishing a processing gas atmosphere 111 having a O₂-content and/or a water vapor content and/or an inert gas content as described herein.

According to embodiments which can be combined with other embodiments described herein, the gas distribution system may be configured for providing H₂ and/or O₂ and/or water vapor and/or inert gas to the processing gas atmosphere inside the vacuum chamber 110 independently from each other. Accordingly, the H₂ content and/or the O₂ content and/or the water vapor content and/or the inert gas content of the processing gas atmosphere 111 within the vacuum chamber 110 can independently be controlled.

According to embodiments which can be combined with other embodiments described herein, the inert gas supply unit 134 may include an inert gas flow controller 164 configured for controlling an amount of inert gas provided to the processing gas atmosphere. Accordingly, the water vapor supply unit 133 may include a water vapor mass flow controller 163 configured for controlling an amount of water vapor provided to the processing gas atmosphere 111, the O₂-supply unit 132 may include an O₂ mass flow controller 162c configured for controlling an amount of water vapor provided to the processing gas atmosphere 111, and the H₂-supply unit 131 may include an a H₂-mass flow controller 161d for controlling an amount of H₂ provided to the processing gas atmosphere 111, as exemplarily shown in FIG. 3. Further, the O₂-supply unit 132 may include an O₂-mass flow meter 162d configured for measuring the O₂-mass flow provided to the vacuum chamber 110. Further, the H₂-supply unit 131 may include a H₂-mass flow meter 161e configured for measuring the H₂-mass flow provided to the vacuum chamber 110. Accordingly, a redundant measurement of the O₂-mass flow and the H_{2—}mass flow provided to the vacuum chamber 110 can be provided.

According to embodiments which can be combined with other embodiments described herein, the H₂-supply unit 131 may be configured for providing an inert gas/H₂ mixture. The partial pressure of the inert gas in the inert gas/H₂ mixture may be selected from a range between a lower limit of inert gas partial pressure and an upper limit of inert gas partial pressure as specified herein. Accordingly, the partial pressure of the H₂ in the inert gas/H₂ mixture may be selected from a range between a lower limit of H₂ partial pressure and an upper limit of H₂ partial pressure as specified herein.

According to embodiments which can be combined with other embodiments described herein, the O₂-supply unit 132 may be configured for providing an inert gas/O₂ mixture. The partial pressure of the inert gas in the inert gas/O₂ mixture may be selected from a range between a lower limit of inert gas partial pressure and an upper limit of inert gas partial pressure as specified herein. Accordingly the partial pressure of the O₂ in the inert gas/O₂ mixture may be selected from a range between a lower limit of O₂ partial pressure and an upper limit of O₂ partial pressure as specified herein.

According to embodiments which can be combined with other embodiments described herein, the water vapor supply unit 133 may be configured for providing an inert gas/water vapor mixture. The partial pressure of the inert gas in the inert gas/water vapor mixture may be selected from a range between a lower limit of inert gas partial pressure and an upper limit of inert gas partial pressure as specified herein. Accordingly the partial pressure of the water vapor in the inert gas/water vapor mixture may be selected from a range between a lower limit of water vapor partial pressure and an upper limit of water vapor partial pressure as specified herein.

According to embodiments which can be combined with other embodiments described herein, the gas distribution system 130 may include pumps and/or compressors for providing the desired pressure of the processing gas atmosphere inside the vacuum chamber. In particular, the gas distribution system may include pumps and/or compressors for providing the partial pressure of inert gas and/or for providing the partial pressure of H₂ and/or for providing the partial pressure of O₂ and/or for providing the partial pressure of water vapor according to the respective partial pressure ranges as specified herein by the respective upper and lower partial pressure limits of inert gas, H₂, O₂ and water vapor. For example, the partial pressures of the gas constituents, e.g. inert gas and/or H₂ and/or O₂ and/or water vapor, of the processing gas atmosphere may be controlled by a respective mass flow controller for the respective gas constituent. The gas constituents may be provided via a direct gas supply from the factory line or a gas reservoir, such as a gas tank.

With exemplarily reference to FIGS. 2 and 3, according to embodiments which can be combined with other embodiments described herein, a turbo pump 141 may be provided for supplying the processing gas from the vacuum chamber 110 to the vacuum system 140. For example, the turbo pump 141 may be provided at the outlet port 115 of the vacuum chamber 110. Additionally, as exemplarily shown in FIGS. 2 and 3, a pre-vacuum pump 142, for example a root pump, may be arranged between the turbo pump 141 and the vacuum pump 143. Accordingly, as exemplarily shown in FIGS. 2 and 3, the pipe 144 to which the dilution gas feeding unit 165 is connected may be a pre-vacuum pipe connecting the turbo pump 141 with the pre-vacuum pump 142.

According to embodiments which can be combined with other embodiments described herein, the dilution gas feeding unit 165 may include a redundant dilution gas measurement system 165a for providing a redundant dilution gas mass flow measurement of the dilution gas provided to the vacuum system 140, as exemplarily shown in FIG. 2. As exemplarily shown in FIG. 3, the redundant dilution gas measurement system 165a may include a dilution gas mass flow controller 165b and a dilution gas mass flow meter 165c. The dilution gas mass flow controller 165b may be configured for controlling and measuring a dilution gas mass flow provided from the dilution gas feeding unit 165 to the vacuum system 140. The dilution gas mass flow meter 165c may be configured for measuring the dilution gas mass flow provided from the dilution gas feeding unit 165 to the vacuum system 140. Accordingly, a safety arrangement for a vacuum sputter deposition apparatus is provided in which the mass flow of the dilution gas provided to the vacuum system can be redundantly measured. Accordingly, the safety of operating the vacuum sputter deposition apparatus with a H₂-content as described herein can be increased.

As exemplarily shown in FIGS. 2 and 3, according to embodiments which can be combined with other embodiments described herein, the redundant dilution gas measurement system 165a may be connected to the gas distribution system 130 for providing a feedback control for controlling a preselected dilution ratio of H₂/dilution gas in the vacuum system 140. In particular, the redundant dilution gas measurement system 165a may be connected to a redundant H₂-mass flow measurement system 161c of the gas distribution system 130. As exemplarily shown in FIG. 3, the redundant H₂-mass flow measurement system 161c may include a H₂-mass flow controller 161d and a H₂-mass flow meter 161e. The H₂-mass flow controller 161d may be configured for controlling and measuring a H₂-mass flow provided to the vacuum chamber 110. The H₂-mass flow meter 161e may be configured for measuring the H₂-mass flow provided to the vacuum chamber 110. Accordingly, a redundant measurement of the H₂-mass flow provided to the vacuum chamber 110 can be provided.

According to embodiments which can be combined with other embodiments described herein, the dilution gas mass flow controller 165b may receive information about the H₂-mass flow provided to the vacuum chamber such that the dilution gas mass flow controller 165b may adjust a preselected dilution gas mass flow for providing a dilution ratio of H₂/dilution gas in the vacuum system as described herein. According to embodiments which can be combined with other embodiments described herein, the preselected dilution ratio of H₂/dilution gas may be at least 1/5, particularly at least 1/10, more particularly at least 1/12. For example, in the case that nitrogen N₂ is employed as dilution gas the dilution ratio of H₂/N₂ is at least 1/16, for example the dilution ratio of H₂/N₂ may be 1/17. As another example, in the case that nitrogen CO₂ is employed as dilution gas the dilution ratio of H₂/CO₂ may be at least 1/12. According to embodiments which can be combined with other embodiments described herein, the dilution gas may be at least one gas selected form the group consisting of: air; carbon dioxide CO_{2;} nitrogen N₂; water vapor H₂O, inert gas, such as of helium He, neon Ne, argon Ar, krypton Kr, xenon Xe or radon Rn. Accordingly, by providing a dilution ratio of H₂/dilution gas in the vacuum system 140 as described herein, the risk of an oxy-hydrogen explosion using a processing gas with a H₂-content from 2.2% to 30% may be reduced or even eliminated.

According to embodiments which can be combined with other embodiments described herein, the dilution gas mass flow controller 165b may be connected to a controller 120, as exemplarily shown in FIG. 3. The controller 120 may be configured for receiving H₂-mass flow measurement data from the redundant H₂-mass flow measurement system 161c. Further, the controller 120 may be configured for receiving dilution gas mass flow measurement data from the redundant dilution gas measurement system 165a. Accordingly, the controller 120 may control the dilution gas mass flow and/or the H₂-mass flow by controlling the dilution gas mass flow controller 165b and/or the H₂-mass flow controller 161d such that a preselected H₂/dilution gas ratio in the vacuum system as described herein may be adjusted and maintained.

According to embodiments which can be combined with other embodiments described herein, the safety arrangement 160 may include a pressure control unit 145 arranged within the vacuum system 140 for measuring the pressure inside the vacuum system 140. For example, the pressure control unit 145 may be arranged in the pipe 144 between the turbo pump 141 and the pre-vacuum pump 142, as exemplarily shown in FIGS. 2 and 3. As exemplarily shown in FIGS. 2 and 3, the pressure control unit 145 may be connected to a redundant H₂-shutdown system 161 of the gas distribution system 130 for shutting down the H₂-supply when a critical pressure of the processing gas within the vacuum system 140 is detected by the pressure control unit 145. As exemplarily shown in FIG. 3 the redundant H₂-shutdown system 161 may include a first H₂-valve 161a and a second H₂-valve 161b which may be closed for shutting down the H₂-supply. For example, the critical pressure at which the pressure control unit 145 may send a signal to the redundant H₂-shutdown system 161 for shutting down the H₂-supply may be a critical pressure from a range between a lower limit of 0.008 mbar, particularly a lower limit of 0.02 mbar, more particularly a lower limit of 0.05 mbar, and an upper limit of 1.0 mbar, particularly an upper limit of 10 mbar, more particularly an upper limit of 50 mbar. For example the critical pressure in the pipe 144, i.e. the pre-vacuum pipe, at which the pressure control unit 145 may send a signal to the redundant H₂-shutdown system 161 for shutting down the H₂-supply may be a critical pressure of 2.0 mbar.

According to embodiments which can be combined with other embodiments described herein, the connection of the pressure control unit 145 with the redundant H₂-shutdown system 161 may be a direct connection such that in the case that a critical pressure of the processing gas within the vacuum system 140 is detected, a signal for shutting down the H₂-supply is directly sent to the redundant H₂-shutdown system 161. For example, the pressure control unit 145, e.g. a pressure sensor, may be triggered mechanically when a critical pressure within the vacuum systems occurs, particularly in the pipe 144 between the turbo pump 141 and the pre-vacuum pump 142. When the first pressure control unit 145 has been triggered, a signal for shutting down the H₂-supply is directly send to the redundant H₂-shutdown system 161, e.g. to the first H₂-valve 161a and the second H₂-valve 161b.

According to embodiments which can be combined with other embodiments described herein, additionally or alternatively the pressure control unit 145 may be connected to the controller 120 which may be configured for receiving measurement data from the pressure control unit 145. For example, in the case that a critical pressure within the vacuum system 140 is detected by the pressure control unit 145, a corresponding signal may be send to the controller 120. The controller may then initiate an appropriate reaction, e.g. sending a signal to the redundant H₂-shutdown system 161 for shutting down the H₂-supply.

As exemplarily shown in FIG. 2, according to embodiments which can be combined with other embodiments described herein, the safety arrangement 160 may further include a redundant processing gas pressure measurement system 150 arranged inside the vacuum chamber 110. As exemplarily shown in FIG. 3, the redundant processing gas pressure measurement system 150 may include a first pressure sensor 150a and a second pressure sensor 150b. The redundant processing gas pressure measurement system 150 may be connected to the redundant H₂-shutdown system 161 for shutting down the H₂-supply when a critical pressure within the vacuum chamber, particularly a critical pressure from a range between a lower limit of 0.008 mbar, particularly a lower limit of 0.02 mbar, more particularly a lower limit of 0.05 mbar, and an upper limit of 1.0 mbar, particularly an upper limit of 10 mbar, more particularly an upper limit of 50 mbar, is detected. According to further embodiments which can be combined with other embodiments described herein, the redundant H₂-shutdown system 161 may be configured for shutting down the H₂-supply when a critical pressure within the vacuum chamber is detected which is 1.5 times higher than the processing pressure, particularly 2 times higher than the processing pressure. The connection of the redundant processing gas pressure measurement system 150 with the redundant H₂-shutdown system 161 may be a direct connection such that in the case that a critical pressure within the vacuum chamber is detected, a signal for shutting down the H₂-supply is directly sent to the redundant H₂-shutdown system 161.

For example, the first pressure sensor 150a and/or the second pressure sensor 150b may be triggered mechanically, for example by a pressure sensitive switch, when a critical pressure within the vacuum chamber 110 occurs. When the first pressure sensor 150a and/or the second pressure sensor 150b have been triggered, a signal for shutting down the H₂-supply is directly sent to the redundant H₂-shutdown system 161, e.g. to the first H₂-valve 161a and the second H₂-valve 161b, for example via a direct electrical connection. Accordingly, by providing a redundant processing gas pressure measurement system as described herein, a safety arrangement for a vacuum sputter deposition apparatus is provided which ensures that an H₂-supply is shut down when a critical pressure is detected within the vacuum chamber.

According to embodiments which can be combined with other embodiments described herein, additionally or alternatively, the redundant processing gas pressure measurement system 150 may be connected to the controller 120 which may be configured for receiving the measurement data from the redundant processing gas pressure measurement system 150. For example, in the case that a critical pressure within the vacuum chamber 110 is detected by the redundant processing gas pressure measurement system 150, a corresponding signal may be send to the controller 120. The controller may then initiate an appropriate reaction, e.g. sending a signal to the redundant H₂-shutdown system 161 for shutting down the H₂-supply.

According to embodiments which can be combined with other embodiments described herein, the gas distribution system 130 may include a redundant H₂-mass flow measurement system 161c for providing a redundant measurement of the H₂ mass flow provided to the vacuum chamber 110, as exemplarily shown in FIG. 2. In particular, the redundant H₂-mass flow measurement system 161c as described herein may be connected with the redundant dilution gas measurement system 165a for adjusting and controlling a preselected dilution ratio of H₂/dilution gas in the vacuum system 140 as described herein. Accordingly, the dilution ratio of H₂/dilution gas as described herein can be controlled and maintained throughout the operation of the deposition apparatus which may be beneficial for reducing or even eliminating the risk of an oxy-hydrogen explosion.

As exemplary shown in FIG. 2, according to embodiments which can be combined with other embodiments described herein, the redundant H₂-mass flow measurement system 161c and/or the redundant H₂-shutdown system 161 may be arranged inside a housing 166. An arrangement of the redundant H₂-mass flow measurement system 161c and/or the redundant H₂-shutdown system 161 inside a housing may be beneficial for detecting a H₂-leakage which may occur at the connection of the redundant H₂-mass flow measurement system 161c and/or the redundant H₂-shutdown system 161 with the H₂-supply pipe. For example, a H₂-leakage may occur at screw couplings with which the H₂-mass flow controller 161d and/or the H2-mass flow meter 161e are connected to the H₂-supply pipe. Further, a H₂-leakage may occur at screw couplings with which the first H₂-valve 161a and/or the second H₂-valve 161b are connected to the H₂-supply pipe. Accordingly, as exemplary shown in FIGS. 2 and 3, the housing 166 may include an exhaust gas line 166a connecting the housing 166 with an outside atmosphere. For example, the exhaust gas line 166a may be connected to the housing via an exhaust gas pump 168 for pumping the gas from the inside of the housing 166 into the exhaust gas line 166a. The exhaust gas line 166a may be provided with a H₂-sensor 167 for detecting an H₂-leakage. The H₂-sensor 167 may be connected with the redundant H₂-shutdown system 161 for shutting down the H₂-supply when a critical H₂-leakage is detected by the H₂-sensor 167. In particular, the redundant H₂-shutdown system 161 may shut down the H₂-supply when a H₂-content in the exhaust gas line is detected which exceeds the H₂-content of air in an ambient atmosphere, e.g. 0.055%×10⁻³. For example, the redundant H₂-shutdown system 161 may shut down the H₂-supply when a H₂-content in the exhaust gas line of at least 0.001%, particularly at least 0.003%, more particularly at least 0.005% is detected. According to another example, the redundant H₂-shutdown system 161 may shut down the H₂-supply when a H₂-content in the exhaust gas line of at least 0.5%, particularly at least 1.0%, more particularly at least 2.0% is detected. Accordingly, an apparatus for vacuum sputter deposition is provided in which the risk of an oxy-hydrogen explosion is reduced or even eliminated.

According to embodiments which can be combined with other embodiments described herein, the safety arrangement 160 may further include a redundant processing gas measurement system 151 for measuring the composition of the processing gas inside the vacuum chamber 110, as exemplarily shown in FIG. 2. In particular, the redundant processing gas measurement system 151 may be configured for measuring the content of at least one gas constituent selected from the group consisting of: H₂; O₂; water vapor; inert gas, e.g. helium, neon, argon, krypton, xenon or radon, and residual gas as described herein. With exemplary reference to FIG. 3, the redundant processing gas measurement system 151 may include a first processing gas sensor 151a and a second processing gas sensor 15lb. The redundant processing gas measurement system 151 may be connected to the redundant H₂-shutdown system 161 for shutting down an H₂-supply when a critical H₂-content of the processing gas is detected. For example, the critical H₂-content of the processing gas at which the redundant H₂-shutdown system 161 may shut down the H₂-supply may be a deviation from a preselected H₂-content by 1% or more, particularly 2% or more, more particularly 3% or more.

According to embodiments which can be combined with other embodiments described herein, the connection of the redundant processing gas measurement system 151 with the redundant H₂-shutdown system 161 may be a direct connection such that in the case that a critical H₂-content of the processing gas within the vacuum chamber is detected, a signal for shutting down the H₂-supply is directly sent to the redundant H₂-shutdown system 161. For example, the first processing gas sensor 151a and/or the second processing gas sensor 151b may be triggered mechanically when a critical H₂-content within the vacuum chamber 110 occurs. When the first processing gas sensor 151a and/or the second processing gas sensor 151b have been triggered, a signal for shutting down the H₂-supply is directly sent to the redundant H₂-shutdown system 161, e.g. to the first H₂-valve 161a and the second H₂-valve 161b. Accordingly, an apparatus for vacuum sputter deposition is provided in which the risk of an oxy-hydrogen explosion is reduced or even eliminated.

According to embodiments which can be combined with other embodiments described herein, the redundant processing gas measurement system 151 may additionally or alternatively be connected to the controller 120 which may be configured for receiving measurement data from the redundant processing gas measurement system 151. For example, in the case that a critical H₂-content within the vacuum chamber 110 is detected by the redundant processing gas measurement system 151, a corresponding signal may be sent to the controller 120. The controller may then initiate an appropriate reaction, e.g. sending a signal to the redundant H₂-shutdown system 161 for shutting down the H₂-supply.

With exemplary reference to FIG. 2, according to embodiments which can be combined with other embodiments described herein, the redundant processing gas pressure measurement system 150 and/or the redundant processing gas measurement system 151 may be connected to a redundant O₂-shutdown system 162 for shutting down the O₂-supply when the critical pressure or a critical H₂-content of the processing gas inside the vacuum chamber 110 is detected. With exemplary reference to FIG. 3, the redundant O₂-shutdown system 162 may include a first O₂-valve 162a and a second O₂-valve 162b which may be closed for shutting down the O₂-supply. As exemplary shown in FIG. 3, the connection of the redundant processing gas pressure measurement system 150 and/or the redundant processing gas measurement system 151 with the redundant O₂-shutdown system 162 may be a direct connection such that in the case that a critical pressure and/or a critical H₂-content of the processing gas within the vacuum chamber is detected, a signal for shutting down the H₂-supply is directly sent to the redundant H₂-shutdown system 161. Accordingly, an apparatus for vacuum sputter deposition is provided in which the risk of an oxy-hydrogen explosion is reduced or even eliminated.

According to embodiments which can be combined with other embodiments described herein, additionally or alternatively, the redundant O₂-shutdown system 162 may receive a signal from the controller 120 for shutting the O₂-supply when the critical pressure and/or a critical H₂-content of the processing gas within the vacuum chamber is detected. For example, in the case that a critical pressure and/or a critical H₂-content within the vacuum chamber 110 is detected by the redundant processing gas pressure measurement system 150 and/or the redundant processing gas measurement system 151, a corresponding signal may be sent to the controller 120. The controller may then initiate an appropriate reaction, e.g. sending a signal to the redundant O₂-shutdown system 162 for shutting down the O₂-supply.

According to embodiments which can be combined with other embodiments described herein, the cathodes can be rotatable cathodes with magnet assemblies 221a, 221b therein, as exemplarily shown in FIG. 3. Accordingly, with the apparatus as described herein, magnetron sputtering may be conducted for depositing a layer. As exemplarily shown in FIG. 3, the first sputter cathode 223a and the second sputter cathode 223b may be connected to a power supply 170. It is to be understood, that in the case that the apparatus includes three or more sputter cathodes the three or more sputter cathodes may be connected to the power supply. Accordingly, the aspects described with respect to the first sputter cathode 223a and the second sputter cathode 223b may also apply for embodiments in which three or more sputter cathodes are implemented.

According to embodiments which can be combined with other embodiments described herein, the power supply 170 may be connected to the controller 120 such that the power supply can be controlled by the controller, as exemplarily shown by the arrow from the controller 120 to the power supply 170 in FIG. 3. Depending on the nature of the deposition process the cathodes may be connected to an AC (alternating current) power supply or a DC (direct current) power supply. For example, sputtering from an indium oxide target, e.g. for a transparent conductive oxide film, may be conducted as DC sputtering. In case of DC sputtering, the first sputter cathode 223a may be connected to a first DC power supply and the second sputter cathode 223b may be connected to a second DC power supply. Accordingly, for DC sputtering the second sputter cathode 223b and the second sputter cathode 223b may have separate DC power supplies. According to embodiments which can be combined with other embodiments described herein, DC sputtering may include pulsed-DC sputtering, particularly bipolar-pulsed-DC sputtering. Accordingly, the power supply may be configured for providing pulsed-DC, particularly bipolar-pulsed-DC. In particular, the first DC power supply for the first sputter cathode 223a and the second DC power supply for the second sputter cathode 223b may be configured for providing pulsed-DC power. In FIG. 3, a horizontal arrangement of sputter cathode and substrate 200 to be coated is shown. In some embodiments, which may be combined with other embodiments disclosed herein, a vertical arrangement of sputter cathodes and the substrate 200 to be coated may be used.

According to embodiments which can be combined with other embodiments described herein, the controller 120 may control the gas distribution system 130 as exemplarily indicated by the arrow 120a in FIG. 3. In particular, the controller may control one or more element(s) selected form the group consisting of: the H₂-supply unit 131; the O₂-supply unit 132; the water vapor supply unit 133; the inert gas supply unit 134; the redundant H₂-shutdown system 161 (e.g. the first H₂-valve 161a and/or the second H₂-valve 161b); the redundant H₂-mass flow measurement system 161c (e.g. the H₂-mass flow controller 161d and the H₂-mass flow meter 161e); the redundant O₂-shutdown system 162 (e.g. the first O₂-valve 162a and the second O₂-valve 162b); the O₂ mass flow controller 162c; the O₂-mass flow meter 162d; the water vapor mass flow controller 163; the inert gas flow controller 164, the dilution gas mass flow controller 165b, the turbo pump 141, the pre-vacuum pump 142 and the vacuum pump 143. Accordingly, it is to be understood that the controller may control all elements of the gas distribution system 130 and/or the vacuum system 140 individually, such that all constituents of a selected processing gas atmosphere with a composition as described herein may be controlled independently from each other and that a dilution ratio of H₂/dilution gas as described herein can be controlled. Accordingly, the composition of a selected processing gas atmosphere can be controlled very accurately and the risk of an oxy-hydrogen explosion using a processing gas with a

H₂-content from 2.2% to 30% may be reduced or even eliminated.

When the apparatus 100 for vacuum sputter deposition as described herein is used for conducting the method of manufacturing at least one layer according to embodiments described herein, a substrate 200 may be disposed below the sputter cathodes, as exemplarily shown in FIGS. 1 to 3. The substrate 200 may be arranged on a substrate support 210. According to embodiments which can be combined with other embodiments described herein, a substrate support device for a substrate to be coated may be disposed in the vacuum chamber. For example, the substrate support device may include conveying rolls, magnet guiding systems and further features. The substrate support device may include a substrate drive system for driving the substrate to be coated in or out of the vacuum chamber 110.

Accordingly, the apparatus according to embodiments as described herein is configured for manufacturing a layer for a plurality of thin film transistors for display manufacturing by employing the method of manufacturing at least one layer according to embodiments described herein.

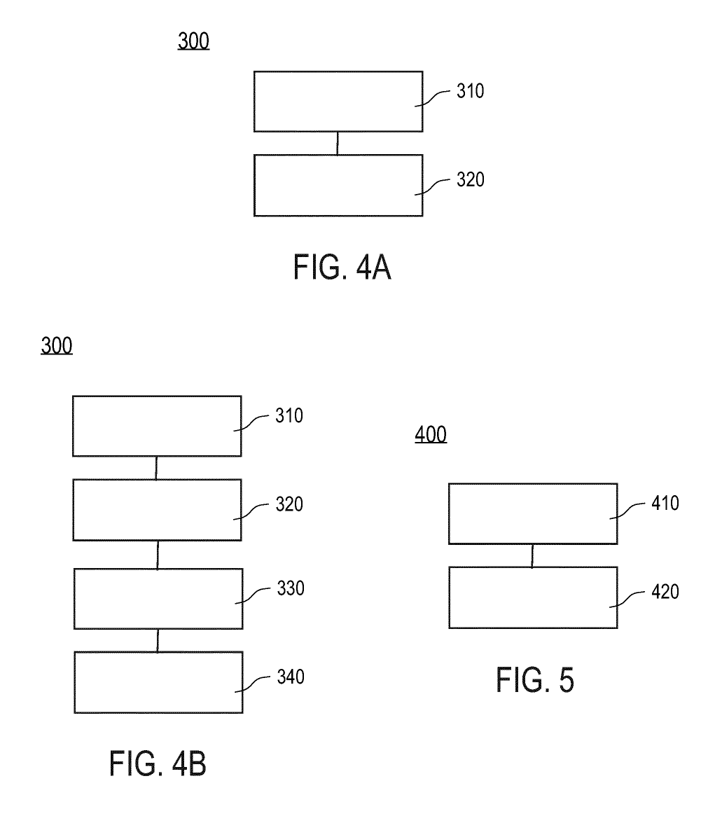

FIG. 4A shows a block diagram illustrating a method 300 for reducing the risk of an oxy-hydrogen explosion in a vacuum deposition apparatus according to embodiments as described herein. The method 300 for reducing the risk of an oxy-hydrogen explosion may include feeding 310 dilution gas to a vacuum system of the vacuum deposition apparatus. For example, feeding 310 dilution gas to a vacuum system may include employing a dilution gas feeding unit 165 as described herein. Further, the method 300 for reducing the risk of oxy-hydrogen explosion may include diluting 320 the H₂-content of the processing gas supplied from the vacuum chamber to the vacuum system 140. In particular, diluting 320 may include diluting the H₂-content of the processing gas supplied to the vacuum system with a dilution ratio of H₂/dilution gas of at least 1/5, particularly at least 1/10, more particularly at least 1/12. Accordingly, embodiments of the method for reducing the risk of oxy-hydrogen explosion in a vacuum deposition apparatus as described herein provide for reducing or even eliminating the risk of an oxy-hydrogen explosion, particularly in the case in which a processing gas with a content of H₂ from 2.2% to 30% is used during vacuum vapor disposition.

With exemplary reference to FIG. 4B, according to embodiments which can be combined with other embodiments described herein, the method 300 for reducing the risk of an oxy-hydrogen explosion may further include redundantly measuring 330 at least one parameter selected form the group consisting of: a dilution gas mass flow provided to the vacuum system, a pressure of the processing gas within the vacuum chamber, and a H₂-content provided to the vacuum chamber. In particular, redundant measuring 330 may include employing at least one system selected of the group consisting of: a redundant dilution gas measurement system 165a as described herein, a redundant processing gas pressure measurement system 150 as described herein, and a redundant processing gas measurement system 151 as described herein.

Further, the method 300 for reducing the risk of an oxy-hydrogen explosion may include shutting down 340 an H₂-supply when at least one parameter selected form the group consisting of: a critical pressure inside the vacuum chamber as described herein, a critical pressure inside the vacuum system as described herein, a critical H₂-content in the vacuum chamber as described herein, a critical H₂-content in an exhaust gas line as described herein, and a non-sufficient dilution ratio of H₂/dilution gas in a vacuum system as described herein is determined. In particular, shutting down 340 an H₂-supply may include employing a redundant H₂-shutdown system as described herein.

Further, the method for reducing the risk of an oxy-hydrogen explosion may include shutting down an O₂-supply when at least one parameter selected form the group consisting of: a critical pressure inside the vacuum chamber as described herein, a critical pressure inside the vacuum system as described herein, a critical H₂-content in the vacuum chamber as described herein, a critical H₂-content in an exhaust gas line as described herein, and a non-sufficient dilution ratio of H₂/dilution gas in a vacuum system as described herein is determined. In particular, shutting down an O₂-supply may include employing a redundant O₂-shutdown system as described herein.

In view of the embodiments of the apparatus for vacuum sputter deposition as described herein as well as in view of the embodiments of the method for reducing the risk of oxy-hydrogen explosion in a vacuum deposition apparatus as described herein, it is to be understood that the apparatus as described herein is configured for depositing material on a substrate in a processing gas atmosphere having a content of H₂ from 2.2% to 30.0%. In particular, the embodiments of the apparatus as described herein provide for an apparatus with which the risk of oxy-hydrogen explosion may be reduced or even eliminated. Accordingly, it is to be understood that embodiments of the apparatus for vacuum sputter deposition as described herein are beneficially used for depositing a layer on a substrate, particularly a transparent conductive oxide layer, e.g. an indium tin oxide (ITO) layer, for display manufacturing in a processing gas atmosphere having a content of H₂ from 2.2% to 30.0%.

Further, it is to be understood that the apparatus for vacuum sputter deposition as described herein is configured for establishing various processing gas atmospheres which can be characterized by different sets of processing parameters, e.g. different processing gas compositions, different processing gas pressures etc. Accordingly, the apparatus as described herein is configured for manufacturing layers and/or layer stacks having different physical properties which may depend on the selected set of processing parameters, as explained in more detail in the following. Additionally, it is to be understood that the method of manufacturing at least one layer and/or the method of manufacturing a layer stack according to embodiments described herein may be conducted independently from the method for reducing the risk of an oxy-hydrogen explosion in a vacuum deposition apparatus as described herein. Further, it is to be understood that the apparatus, particularly the safety arrangement for reducing risk of an oxy-hydrogen explosion, and the method for reducing risk of an oxy-hydrogen explosion may be adapted for reducing the risk of explosion for any other explosive or flammable gases, for example methane etc.

With exemplary reference to FIG. 5, embodiments of a method 400 of manufacturing at least one layer are described. According to embodiment described herein, the method 400 of manufacturing a layer may include sputtering 410 a layer from a sputter material containing cathode onto a substrate 200 in a processing gas atmosphere 111 within a vacuum chamber 110, wherein the substrate 200 may be at rest or in continuous movement during sputtering. It is to be understood that the expression, “the substrate may be at rest” may refer to a static deposition process as described herein, whereas the expression, “the substrate may be in continuous movement” may refer to a dynamic deposition process as described herein. The processing gas during the manufacture of the at least one layer may include H₂ with a content of H₂ from 2.2% to 30.0%. Further, according to embodiments which can be combined with other embodiments described herein, the method 400 of manufacturing at least one layer may include conducting 420 the method 300 for reducing the risk of oxy-hydrogen explosion as described herein.

According to embodiments which can be combined with other embodiments described herein, the processing gas atmosphere 111 may include H₂, O₂ and an inert gas. The inert gas may be selected from the group consisting of helium, neon, argon, krypton, xenon or radon. In particular the inert gas may be argon (Ar). It is to be understood that the content of the constituents of the processing gas atmosphere according to embodiments described herein may add up to 100%. For example, the content of H₂, O₂ and inert gas of a processing gas atmosphere 111 including H₂, O₂ and an inert gas may add up to 100%. According to embodiments which can be combined with other embodiments described herein, the method of manufacturing at least one layer as described herein may be carried out at room temperature.

According to embodiments which can be combined with other embodiments described herein, the method 400 of manufacturing at least one layer may include sputtering a transparent conductive oxide layer from an indium oxide containing target in a processing gas atmosphere 111 wherein the processing gas atmosphere 111 includes H₂, O₂, and an inert gas, wherein the content of H₂ is from 2.2% to 30.0%, wherein the content of O₂ is from 0.0% to 30.0%, and wherein the content of inert gas is from 65.0% to 97.8%.

According to embodiments which can be combined with other embodiments described herein, the content of H₂ in the processing gas atmosphere 111 may be selected from a range between a lower limit of 2.2%, particularly a lower limit of 3.0%, particularly a lower limit of 4.2%, more particularly a lower limit of 6.1%, and an upper limit of 10%, particularly an upper limit of 15.0%, more particularly an upper limit of 30.0%. With respect to the lower limits of H₂ it is to be understood that the lower explosion limit of H₂ is 4.1% and the total inertisation limit is 6.0%. By sputtering a transparent conductive oxide layer from an indium oxide containing target in a processing gas atmosphere in which the content of H₂ in the processing gas atmosphere has been selected from a range between a lower limit and an upper limit as described herein, the degree of amorphous structure of the oxide layer may be adjusted. In particular, by increasing the content of H₂ in the processing gas atmosphere the degree of amorphous structure in the oxide layer may be increased.

Accordingly, by sputtering a transparent conductive oxide layer from an indium containing target in a processing gas atmosphere having a content of H₂ as described herein, the formation of a crystalline ITO phase may be suppressed. In view of that, in the case of a subsequent patterning of the sputtered oxide layer, for example by wet chemical etching, a reduction in crystalline ITO residuals on the substrate can be achieved. Accordingly, the quality of a patterned oxide layer employed for TFT display manufacturing can be increased.

According to embodiments which can be combined with other embodiments described herein, the content of O₂ in the processing gas atmosphere 111 may be from a range between a lower limit of 0.0%, particularly a lower limit of 1.0%, more particularly a lower limit of 1.5%, and an upper limit of 8.0%, particularly an upper limit of 10.0%, more particularly an upper limit of 30.0%. By sputtering a transparent conductive oxide layer from an indium oxide containing target in a processing gas atmosphere in which the content of O₂ in the processing gas atmosphere has been selected from a range between a lower limit and an upper limit as described herein, the sheet resistance of the oxide layer may be adjusted and optimized with respect to low resistance. In particular, for optimizing the sheet resistance with respect to low resistance, the content of O₂ has to be selected from a range between a lower critical value and an upper critical value. For, example in case the content of O₂ is below the lower critical value or above the upper critical value, relatively high values for the sheet resistance may be obtained. Accordingly, embodiments as described herein provide for adjusting and optimizing the sheet resistance oxide layers with respect to low resistance.

According to embodiments which can be combined with other embodiments described herein, the content of inert gas is in the processing gas atmosphere may be from a range between a lower limit of 20%, particularly a lower limit of 40%, more particularly a lower limit of 75%, and an upper limit of 91.5%, particularly an upper limit of 94.0%, more particularly an upper limit of 97.3%. By sputtering a transparent conductive oxide layer from an indium oxide containing target in a processing gas atmosphere in which the content of inert gas in the processing gas atmosphere has been selected from a range between a lower limit and an upper limit as described herein, the quality of the transparent conductive oxide layer can be ensured. In particular, by providing a processing gas atmosphere with inert gas as described herein, the risk of flammability and explosion of H₂ in the processing gas atmosphere can be reduced or even eliminated.

According to embodiments which can be combined with other embodiments described herein, the processing gas atmosphere may consist of H₂, O₂, an inert gas and a residual gas. The content of H₂, O₂ and inert gas in the processing gas atmosphere consisting of H₂, O₂ and inert gas may be selected from a range between a respective lower limit and a respective upper limit as described herein. The residual gas may be any impurity or any contaminant in the processing gas atmosphere. In the processing gas atmosphere consisting of H₂, O₂, inert gas and a residual gas, the content of residual gas may be from 0.0% to 1.0% of the processing gas atmosphere. According to embodiments which can be combined with other embodiments described herein, the content of residual gas is 0.0% of the processing gas atmosphere. It is to be understood that the content of the constituents of the processing gas atmosphere according to embodiments described herein may add up to 100%. In particular, the content of H₂, O₂, inert gas and residual gas may add up to 100% of the processing gas atmosphere in the case that residual gas is present in the processing gas atmosphere or in the case that the processing gas atmosphere contains no residual gas, i.e. the content of the residual gas is 0.0%.

According to embodiments which can be combined with other embodiments described herein, the total pressure of the processing gas atmosphere 111 may be from 0.08 Pa to 3.0 Pa. According to embodiments which can be combined with other embodiments described herein, the total pressure of the processing gas atmosphere 111 may be from a range between a lower limit of 0.2 Pa, particularly a lower limit of 0.3 Pa, more particularly a lower limit of 0.4 Pa, and an upper limit of 0.6 Pa, particularly an upper limit of 0.7 Pa, more particularly an upper limit of 0.8 Pa. In particular, the total pressure of the processing gas atmosphere may be 0.3 Pa. By sputtering a transparent conductive oxide layer from an indium oxide containing target in a processing gas atmosphere in which the total pressure of the processing gas atmosphere has been selected from a range between a lower limit to an upper limit as described herein, the degree of amorphous structure of the oxide layer may be adjusted. In particular, by increasing the total pressure of the processing gas atmosphere the degree of amorphous structure in the oxide layer may be increased.

According to embodiments which can be combined with other embodiments described herein, all constituent gases of the processing gas atmosphere may be mixed prior to establishing the processing gas atmosphere in the vacuum chamber. Accordingly, prior to sputtering or during sputtering the transparent conductive oxide layer all constituent gases of the processing gas atmosphere may be supplied to the vacuum chamber through the same gas showers. In particular, depending on the selected composition of the processing gas atmosphere as described herein, H2, O2 and inert gas may be supplied to the vacuum chamber through the same gas showers, for example the gas shower 135 as exemplarily shown in FIGS. 1 to 3. Alternatively, the constituents of the processing gas atmosphere, e.g. H2, O2 and inert gas, may be provided through separate gas showers.

According to embodiments which can be combined with other embodiments described herein, the partial pressure of H₂ in the processing gas atmosphere 111 may be from 0.0044 Pa to 0.24 Pa. According to embodiments which can be combined with other embodiments described herein, the partial pressure of H₂ in the processing gas atmosphere 111 may be from a range between a lower limit of 0.0044 Pa, for example in a case in which the lower limit of the H₂ content of 2.2% has been selected for a processing gas atmosphere with the lower limit of the total pressure of 0.2 Pa, and an upper limit of 0.24 Pa, for example in a case in which the upper limit of the H₂ content of 30.0% has been selected for a processing gas atmosphere with the upper limit of the total pressure of 0.8 Pa.

Accordingly, it will be understood that the partial pressure of H₂ in the processing gas atmosphere can be calculated by the product of the selected H₂ content in percent [%] of the processing gas atmosphere and the selected total pressure of the processing gas atmosphere in Pascal [Pa]. Accordingly, depending on the selected values of the upper and lower limits of H₂ content in the processing gas atmosphere and the selected values of the upper and lower limits of the total pressure of the processing gas atmosphere, the corresponding values for the lower and upper limit of the partial pressure of H₂ in the processing gas atmosphere can be calculated and selected.

According to embodiments which can be combined with other embodiments described herein, the partial pressure of O₂ in the processing gas atmosphere 111 may be from 0.001 Pa to 0.24 Pa. According to embodiments which can be combined with other embodiments described herein, the partial pressure of O2 in the processing gas atmosphere may be from a range between a lower limit of 0.001 Pa, for example in a case in which the lower limit of the O₂ content of 0.5% has been selected for a processing gas atmosphere with the lower limit of the total pressure of 0.2 Pa, and an upper limit of 0.24 Pa, for example in a case in which the upper limit of the O₂ content of 30.0% has been selected for a processing gas atmosphere with the upper limit of the total pressure of 0.8 Pa.

Accordingly, it will be understood that the partial pressure of O₂ in the processing gas atmosphere can be calculated by the product of the selected O₂ content in percent [%] of the processing gas atmosphere and the selected total pressure of the processing gas atmosphere in Pascal [Pa]. Accordingly, depending on the selected values of the upper and lower limits of O₂ content in the processing gas atmosphere and the selected values of the upper and lower limits of the total pressure of the processing gas atmosphere, the corresponding values for the lower and the upper limit of the partial pressure of O₂ in the processing gas atmosphere can be calculated and selected.

According to embodiments which can be combined with other embodiments described herein, the partial pressure of inert gas in the processing gas atmosphere 111 may be from 0.08 Pa to 0.7784 Pa. According to embodiments which can be combined with other embodiments described herein, the partial pressure of inert gas in the processing gas atmosphere may be from a range between a lower limit of 0.08 Pa, for example in a case in which the lower limit of the inert gas content of 40% has been selected for a processing gas atmosphere with the lower limit of the total pressure of 0.2 Pa, and a upper limit of 0.7784 Pa, for example in a case in which the upper limit of the inert gas content of 97.3% have been selected for a processing gas atmosphere with the upper limit of the total pressure of 0.8 Pa.

Accordingly, it will be understood that the partial pressure of inert gas in the processing gas atmosphere can be calculated by the product of the selected inert gas content in percent [%] of the processing gas atmosphere and the selected total pressure of the processing gas atmosphere in Pascal [Pa]. Accordingly, depending on the selected values of the upper and lower limits of inert gas content in the processing gas atmosphere and the selected values of the upper and lower limits of the total pressure of the processing gas atmosphere, the corresponding values for the lower and the upper limit of the partial pressure of inert gas in the processing gas atmosphere can be calculated and selected.

According to embodiments which can be combined with other embodiments described herein, the method 400 of manufacturing at least one layer may include providing H₂ and O₂ separately to the processing gas atmosphere 111. Accordingly, the content of H₂ and O₂ in the processing gas atmosphere may be controlled independently from each other. Accordingly, high control over the properties of the transparent conductive oxide layer, e.g. the degree of amorphous structure and the sheet resistance, can be achieved.

According to embodiments which can be combined with other embodiments described herein, H₂ may be provided to the processing gas atmosphere in an inert gas/H₂ mixture. By providing H₂ to the processing gas atmosphere in an inert gas/H₂ mixture, the risk of flammability and explosion of H₂ in the gas distribution system can be reduced or even eliminated. The partial pressure of the inert gas in the inert gas/H₂ mixture may be selected from a range between a lower limit of inert gas partial pressure and an upper limit of inert gas partial pressure as specified herein. The partial pressure of the H₂ in the inert gas/H₂ mixture may be selected from a range between a lower limit of H2 partial pressure and an upper limit of H2 partial pressure as specified herein.

According to embodiments which can be combined with other embodiments described herein, O₂ is provided to the processing gas atmosphere in an inert gas/O₂ mixture. The partial pressure of the inert gas in the inert gas/O₂ mixture may be selected from a range between a lower limit of inert gas partial pressure and an upper limit of inert gas partial pressure as specified herein. The partial pressure of the O₂ in the inert gas/O₂ mixture may be selected from a range between a lower limit of O₂ partial pressure and an upper limit of O₂ partial pressure as specified herein

According to embodiments which can be combined with other embodiments described herein, the method 400 of manufacturing at least one layer may include controlling the degree of amorphous structure of the oxide layer with the content of H₂ in the processing gas atmosphere 111. In particular, by increasing the content of H₂ in the processing gas atmosphere, the degree of amorphous structure in the oxide layer may be increased. In particular, by increasing the content of H₂ in the processing gas atmosphere the number of crystalline grains, particularly at the substrate layer interface may be decreased.

According to embodiments which can be combined with other embodiments described herein, the method 400 of manufacturing at least one layer may include controlling the sheet resistance of the oxide layer with the content of O₂ in the processing gas atmosphere 111. In particular, for optimizing the sheet resistance with respect to low resistance after an annealing, the content of O₂ in the processing gas atmosphere during layer deposition has to be selected from a range between a lower limit and an upper limit as described herein. According to embodiments, after layer deposition an annealing procedure may be performed, for example in a temperature range from 160° C. to 320° C.

According to embodiments which can be combined with other embodiments described herein, the resistivity after annealing of the oxide layer may be from a range between a lower limit of 100 μOhm cm, particularly a lower limit of 125 μOhm cm, more particularly a lower limit of 150 μOhm cm, and an upper limit of 250 μOhm cm, particularly an upper limit of 275 μOhm cm, more particularly an upper limit of 400 μOhm cm. In particular, the resistivity after annealing of the oxide layer may be approximately 230 μOhm cm.

According to embodiments which can be combined with other embodiments described herein, the method of manufacturing a layer for a plurality of thin film transistors for display manufacturing may further include patterning the layer, for example by etching, in particular wet chemical etching. Further, the method of manufacturing a layer according to embodiments described herein may include annealing the layer, for example after patterning.

According to embodiments which can be combined with other embodiments described herein, the method 400 of manufacturing at least one layer may include sputtering a transparent conductive oxide layer from an indium oxide containing target in a processing gas atmosphere 111, wherein the processing gas atmosphere 111 includes water vapor, H₂, and an inert gas. The content of water vapor may be from 1% to 20%. The content of H₂ may be from 2.2% to 30.0%. The content of inert gas may be from 45.0% to 96.8%. It is to be understood that according to some embodiments which can be combined with other embodiments described herein, the content of water vapor, H₂, and inert gas may add up to 100% of the processing gas atmosphere.

According to embodiments which can be combined with other embodiments described herein, the content of water vapor in the processing gas atmosphere may be from a range between a lower limit of 1%, particularly a lower limit of 2.0%, more particularly a lower limit of 4%, and an upper limit of 6%, particularly an upper limit of 8%, more particularly an upper limit of 20.0%. By sputtering a transparent conductive oxide layer from an indium oxide containing target in a processing gas atmosphere in which the content of water vapor in the processing gas atmosphere has been selected from a range between a lower limit and an upper limit as described herein, the degree of amorphous structure of the oxide layer may be adjusted. In particular, by increasing the content of water vapor in the processing gas atmosphere, the degree of amorphous structure in the oxide layer may be increased.

According to embodiments which can be combined with other embodiments described herein, the content of H₂ in the processing gas atmosphere may be from a range between a lower limit of H₂ and an upper limit of H₂ as described herein.

Accordingly, by sputtering a transparent conductive oxide layer from an indium containing target in a processing gas atmosphere having a content of water vapor and a content of H₂ as described herein, the formation of a crystalline ITO phase may be suppressed. In view of that, in case of a subsequent patterning of the sputtered oxide layer, for example by wet chemical etching, a reduction in crystalline ITO residuals on the oxide layer can be achieved. Accordingly, the quality of a patterned oxide layer employed for TFT display manufacturing can be increased. Further, by providing a processing gas atmosphere having a content of water vapor and a content of H₂ as described herein, the risk of flammability and explosion of H₂ in the processing gas atmosphere can be reduced or even eliminated.

According to embodiments which can be combined with other embodiments described herein, the content of inert gas in the processing gas atmosphere may be from a range between a lower limit of 60%, particularly a lower limit of 73%, more particularly a lower limit of 81%, and an upper limit of 87.5%, particularly an upper limit of 92.0%, more particularly an upper limit of 96.3%. By sputtering a transparent conductive oxide layer from an indium oxide containing target in a processing gas atmosphere in which the content of inert gas in the processing gas atmosphere has been selected from a range between a lower limit and an upper limit as described herein, the quality of the transparent conductive oxide layer can be ensured. In particular, by providing a processing gas atmosphere with inert gas as described herein, the risk of flammability and explosion of H₂ in the processing gas atmosphere can be reduced or even eliminated.

According to embodiments which can be combined with other embodiments described herein, the ratio of water vapor to H₂ is from a range between a lower limit of 4:1, particularly a lower limit 2:1, more particularly a lower limit of 1:1.5, and an upper limit of 1:2, particularly an upper limit of 1:3, more particularly an upper limit of 1:4. By sputtering a transparent conductive oxide layer from an indium oxide containing target in a processing gas atmosphere in which the ratio of water vapor to H₂ content in the processing gas atmosphere has been selected from a range between a lower limit and an upper limit as described herein, the control over the degree of amorphous structure in the oxide layer is improved. Accordingly, the degree of amorphous structure can be controlled more precisely, for example compared to a case in which the degree of amorphous structure in the oxide layer may only be controlled by water vapor.

According to embodiments which can be combined with other embodiments described herein, the total pressure of the processing gas atmosphere 111 may be from be from a range between a lower limit of total pressure and an upper limit of total pressure as described herein, in particular the total pressure of the processing gas atmosphere may be from 0.08 Pa to 3.0 Pa.

According to embodiments which can be combined with other embodiments described herein, the partial pressure of water vapor in the processing gas atmosphere may be from a range between a lower limit of 0.004 Pa, for example in a case in which the lower limit of the water vapor content of 2.0% has been selected for a processing gas atmosphere with the lower limit of the total pressure of 0.2 Pa, and an upper limit of 0.16 Pa, for example in a case in which the upper limit of the water vapor content of 20.0% has been selected for a processing gas atmosphere with the upper limit of the total pressure of 0.8 Pa.

Accordingly, it will be understood that the partial pressure of water vapor in the processing gas atmosphere can be calculated by the product of the selected water vapor content in percent [%] of the processing gas atmosphere and the selected total pressure of the processing gas atmosphere in Pascal [Pa]. Accordingly, depending on the selected values of the upper and lower limits of water vapor content in the processing gas atmosphere and the selected values of the upper and lower limits of the total pressure of the processing gas atmosphere corresponding values for the lower and the upper limit of the partial pressure of water vapor in the processing gas atmosphere can be calculated and selected.

According to embodiments which can be combined with other embodiments described herein, the in the processing gas atmosphere 111 may be from a range between a lower limit of H₂-partial pressure and an upper limit of H₂-partial pressure as described herein.

According to embodiments which can be combined with other embodiments described herein, the processing gas atmosphere 111 may further include O₂. The content of O₂ in the processing gas atmosphere may be from a range between a lower limit of the O₂-content and an upper limit of the O₂-content, as described herein.

According to embodiments which can be combined with other embodiments described herein, the partial pressure of O₂ in the processing gas atmosphere 111 from a range between a lower limit of O₂-partial pressure and an upper limit of O₂-partial pressure as described herein.

It is to be understood that according to some embodiments described herein in which the processing gas atmosphere includes water vapor, H₂, inert gas and O₂, the respective contents of water vapor, H₂, inert gas and O₂ may add up to 100% of the processing gas atmosphere.

According to embodiments which can be combined with other embodiments described herein, the partial pressure of inert gas in the processing gas atmosphere may be from a range between a lower limit of 0.04 Pa, for example in a case in which the lower limit of the inert gas content of 20%, the upper limit of the water vapor content of 20%, the upper limit of the H₂ content of 30%, and the upper limit of the O₂ content of 30.0% has been selected for a processing gas atmosphere with the lower limit of the total pressure of 0.2 Pa, and an upper limit of 0.7704 Pa, for example in a case in which the upper limit of the inert gas content of 96.3%, the lower limit of the water vapor content of 1%, the lower limit of the H₂ content of 2.2%, and the lower limit of the O₂ content of 0.5% have been selected for a processing gas atmosphere with the upper limit of the total pressure of 0.8 Pa.

According to embodiments which can be combined with other embodiments described herein, the method 400 of manufacturing at least one layer may further include controlling the degree of amorphous structure of the oxide layer with the content of water vapor in the processing gas atmosphere 111 and/or the content of H2 in the processing gas atmosphere 111. In particular, by increasing the content of water vapor and/or content of H₂ in the processing gas atmosphere, the degree of amorphous structure in the oxide layer may be increased. In particular, by increasing the content of H₂ in the first processing gas atmosphere the number of crystalline grains, particularly at the interface between the substrate and the first layer may be decreased.

According to embodiments which can be combined with other embodiments described herein, the method 400 of manufacturing at least one layer may further include controlling the sheet resistance of the oxide layer with the content of water vapor in the processing gas atmosphere. In particular, for optimizing the sheet resistance of the layer stack with respect to low resistance after an annealing, the content of O₂ in the processing gas atmosphere during layer deposition has to be selected from a range between a lower limit and an upper limit as described herein. According to embodiments, after layer deposition an annealing procedure may be performed, for example in a temperature range from 160° C. to 320° C.

According to embodiments which can be combined with other embodiments described herein, the resistivity after annealing of transparent conductive oxide layer may be from a range between a lower limit of 100 μOhm cm, particularly a lower limit of 210 μOhm cm, more particularly a lower limit of 220 μOhm cm, and an upper limit of 260 μOhm cm, particularly an upper limit of 280 μOhm cm, more particularly an upper limit of 400 μOhm cm. In particular, the resistivity after annealing of the oxide layer may be approximately 230 μOhm cm.

According to embodiments which can be combined with other embodiments described herein, the method 400 of manufacturing at least one layer may further include controlling the sheet resistance of the oxide layer with the content of O₂ in the processing gas atmosphere 111.

According to embodiments which can be combined with other embodiments described herein, the processing gas atmosphere 111 may consist of water vapor, H₂, an inert gas, O₂, and a residual gas, wherein the content of water vapor is from 1% to 20%; wherein the content of H₂ is from 2.2% to 30.0%, wherein the content of inert gas is from 45.0% to 96.3%, wherein the content of O₂ is from 0.0% to 30.0%, and wherein the content of residual gas is from 0.0 to 1.0%. The residual gas may be any impurity or any contaminant in the processing gas atmosphere. In the processing gas atmosphere consisting of water vapor, H₂, inert gas, O₂ and a residual gas, the content of residual gas may be from 0.0% to 1.0% of the processing gas atmosphere. According to embodiments which can be combined with other embodiments described herein, the content of residual gas is 0.0% of the processing gas atmosphere. It is to be understood that the content of the constituents of the processing gas atmosphere according to embodiments described herein may add up to 100%. For example, the content of water vapor, H₂, inert gas, O₂ and a residual gas may add up to 100% of the processing gas atmosphere in a case in which residual gas is present in the processing gas atmosphere or in a case in which the processing gas atmosphere contains no residual gas, i.e. the content of the residual gas is 0.0%.

According to embodiments which can be combined with other embodiments described herein, sputtering 410 a layer onto a substrate may include sputtering a first layer with a first set of processing parameters from an indium oxide containing target. According to embodiments which can be combined with other embodiments described herein, the first set of processing parameters may include at least one first parameter selected from the group consisting of: H2-content provided in a first processing gas atmosphere; content of water vapor provided in the first processing gas atmosphere; O₂-content provided in the first processing gas atmosphere; first total pressure of the first processing gas atmosphere; and a first power supplied to the indium oxide containing target. According to embodiments which can be combined with other embodiments described herein, sputtering the first layer may be carried out at room temperature.

According to embodiments which can be combined with other embodiments described herein, the content of H₂ in the first processing gas atmosphere may be from a range between a lower limit of 2.2%, particularly a lower limit of 4.2%, more particularly a lower limit of 6.1%, and an upper limit of 10%, particularly an upper limit of 15.0%, more particularly an upper limit of 30.0%. With respect to the lower limits of H₂ it is to be understood that the lower explosion limit of H₂ is 4.1% and the total inertisation limit is 6.0%. By sputtering the first layer, for example a first conductive oxide layer of a layer stack, from an indium oxide containing target in a first processing gas atmosphere in which the content of H₂ in the first processing gas atmosphere has been selected from a lower limit to an upper limit as described herein, the etchability of a layer stack may be adjusted.

In particular, the etchability of the layer stack depends on the degree of amorphous structure of the layer stack which can, for example, be controlled by the content of H₂ in the first processing gas atmosphere. In the present disclosure, the expression “degree of amorphous structure” may be understood as the ratio of amorphous structure to non-amorphous structure in the solid state. The non-amorphous structure may be a crystalline structure whereas the amorphous structure may be a glass-like structure. For example, by increasing the content of H₂ in the first processing gas atmosphere, the degree of amorphous structure in the first layer of the layer stack may be increased. Accordingly, the etchability of the layer stack can be improved.

According to embodiments which can be combined with other embodiments described herein, the content of water vapor in the first processing gas atmosphere may be from a range between a lower limit of 0.0%, particularly a lower limit of 2.0%, more particularly a lower limit of 4.0%, and an upper limit of 6.0%, particularly an upper limit of 8.0%, more particularly an upper limit of 20.0%. By sputtering the first layer, for example a first conductive oxide layer of a layer stack, from an indium oxide containing target in a first processing gas atmosphere in which the content of water vapor in the first processing gas atmosphere has been selected from a range between a lower limit and an upper limit as described herein, the etchability of a layer stack may be adjusted. In particular, the etchability of the layer stack depends on the degree of amorphous structure of the layer stack which can, for example, be controlled by the content of water vapor in the first processing gas atmosphere. Particularly, by increasing the content of water vapor in the first processing gas atmosphere the degree of amorphous structure in the first layer of the layer stack may be increased. Accordingly, the etchability of the layer stack can be improved.

According to embodiments which can be combined with other embodiments described herein, the ratio of water vapor to H₂ is from a range between a lower limit of 1:1, particularly a lower limit 1:1.25, more particularly a lower limit of 1:1.5, and an upper limit of 1:2 particularly an upper limit of 1:3, more particularly an upper limit of 1:4. By sputtering a transparent conductive oxide layer from an indium oxide containing target in a processing gas atmosphere in which the ratio of water vapor to H₂ content in the processing gas atmosphere has been selected from a range between a lower limit and an upper limit as described herein, the control over the degree of amorphous structure in the oxide layer is improved. Accordingly, the degree of amorphous structure can be controlled more precisely, for example compared to a case in which the degree of amorphous structure in the oxide layer may only be controlled by water vapor.

According to some embodiments which can be combined with other embodiments described herein, the content of O₂ in the first processing gas atmosphere may be from a range between a lower limit of 0.0%, particularly a lower limit of 1.0%, more particularly a lower limit of 1.5%, and an upper limit of 3.0%, particularly an upper limit of 4.0%, more particularly an upper limit of 30.0%.

According to embodiments which can be combined with other embodiments described herein, all constituent gases of the first processing gas atmosphere may be mixed prior to filling the vacuum chamber with the first processing gas atmosphere. Accordingly, during deposition of the first layer in the first processing gas atmosphere all constituent gases of the first processing gas atmosphere may flow through the same gas showers. In particular, depending on the selected composition of the first processing gas atmosphere as described herein, H₂, water vapor, O₂ and inert gas may be supplied to the vacuum chamber through the same gas showers, e.g. the gas shower 135 as schematically shown in FIGS. 1 to 3. For example, the gaseous constituents of a selected first processing gas atmosphere may be mixed in the gas showers before the gaseous constituents of the selected first processing gas are provided into the vacuum chamber. Accordingly, a very homogenous processing first gas atmosphere can be established in the vacuum chamber.

Accordingly, by sputtering a first layer, for example of a layer stack, from an indium containing target in a processing gas atmosphere having a content of water vapor and/or a content of H₂ as described herein, the formation of a crystalline ITO phase may be suppressed. In view of that, in the case of a subsequent patterning of the sputtered oxide layer, for example by chemical etching, a reduction in crystalline ITO residuals on the oxide layer can be achieved. Accordingly, the quality of a patterned oxide layer employed for TFT display manufacturing can be increased. Further, by providing a processing gas atmosphere having a content of water vapor and a content of H₂ as described herein, the risk of flammability and explosion of H₂ in the processing gas atmosphere can be reduced or even eliminated.

According to embodiments which can be combined with other embodiments described herein, the first total pressure of the first processing gas atmosphere may be from 0.08 Pa to 3.0 Pa. For example, the first total pressure of the first processing gas atmosphere may be from a range between a lower limit of 0.2 Pa, particularly a lower limit of 0.3 Pa, more particularly a lower limit of 0.4 Pa, and an upper limit of 0.6 Pa, particularly an upper limit of 0.7 Pa, more particularly an upper limit of 0.8 Pa. In particular, the total pressure of the first processing gas atmosphere may be 0.3 Pa. By sputtering the first layer, for example of a layer stack, from an indium oxide containing target in a processing gas atmosphere in which the first total pressure of the processing gas atmosphere has been selected from a lower limit to an upper limit as described herein, the etchability of the layer stack may be adjusted. In particular, the etchability of the layer stack depends on the degree of amorphous structure of the layer stack which can, for example, be controlled by the total pressure in the first processing gas atmosphere. In particular, by increasing the total pressure of the first processing gas atmosphere the degree of amorphous structure in the first layer, for example of a layer stack, may be increased. Accordingly, the etchability of the first layer or the etchability of a layer stack including the first layer can be improved.

According to embodiments which can be combined with other embodiments described herein, the first power supplied to the indium oxide containing target may be from a range between a lower limit of 1 kW, particularly a lower limit of 2 kW, more particularly a lower limit of 4 kW, and an upper limit of 5 kW, particularly an upper limit of 10 kW, more particularly an upper limit of 15 kW. For example, in case of using a Gen 8.5 target having a target length of 2.7 m, the target may be provided with a power from a range between of 0.4 kW/m and 5.6 kW/m. According to further embodiments which can be combined with other embodiments described herein, the first power supplied to the indium oxide containing target may be normalized with respect to the substrate size. For example, the substrate may have a size of 5.5 m². Accordingly, it is to be understood that that respective lower limits and upper limits of the first power supplied to the target may be normalized with respect to the length of the target and/or the substrate size. By sputtering the first layer, for example of a layer stack, from an indium oxide containing target with a first power which has been selected from a range between a lower limit and an upper limit as described herein, the degree of amorphous structure of the oxide layer may be adjusted. In particular, by decreasing the first power supplied to the indium oxide containing target, the degree of amorphous structure in the first layer, for example a first layer of a layer stack, may be increased.

According to embodiments which can be combined with other embodiments described herein, sputtering 410 a layer onto a substrate may include sputtering a second layer with a second set of processing parameters from an indium oxide containing target. For example, sputtering the second layer may include sputtering the second layer onto a first layer as described herein. The second set of processing parameters may be different from the first set of processing parameters as described herein.

According to embodiments which can be combined with other embodiments described herein, the second set of processing parameters includes at least one second parameter selected from the group consisting of: H₂-content provided in a second processing gas atmosphere; content of water vapor provided in the second processing gas atmosphere; O₂-content provided in a second processing gas atmosphere; a second total pressure of the second processing gas atmosphere; and a second power supplied to the indium oxide containing target. According to embodiments which can be combined with other embodiments described herein, sputtering the second layer may be carried out at room temperature.

According to some embodiments which can be combined with other embodiments described herein, the content of O₂ in the second processing gas atmosphere may be from a range between a lower limit of 0.0%, particularly a lower limit of 1.0%, more particularly a lower limit of 1.5%, and an upper limit of 3.0%, particularly an upper limit of 4.0%, more particularly an upper limit of 30.0%. By sputtering the second layer, for example of a layer stack, from an indium oxide containing target in a second processing gas atmosphere in which the content of O₂ in the processing gas atmosphere has been selected from a range between a lower limit and an upper limit as described herein, the sheet resistance of the second layer or the sheet resistance of a layer stack including the second layer may be adjusted and optimized with respect to low resistance.

For example, for optimizing the sheet resistance with respect to low resistance, the content of O₂ has to be selected from a range between a lower critical value and an upper critical value. For, example in case the content of O₂ is below the lower critical value or above the upper critical value, relatively high values for the sheet resistance may be obtained. Accordingly, embodiments as described herein provide for adjusting and optimizing the sheet resistance of oxide layers, particularly of oxide layer stacks, with respect to low resistance.

In the present disclosure, the expression “sheet resistance” may be understood as the resistance of a layer manufactured by the method according to embodiments described herein. In particular, “sheet resistance” may refer to a case in which the layer is considered as a two-dimensional entity. It may be understood that the expression “sheet resistance” implies that the current is along the plane of the layer (i.e. the current is not perpendicular to the layer). Further, sheet resistance may refer to a case of resistivity for a uniform layer thickness.

According to embodiments which can be combined with other embodiments described herein, the content of H₂ in the second processing gas atmosphere may be from a range between a lower limit of 2.2%, particularly a lower limit of 5.0%, more particularly a lower limit of 7.0%, and an upper limit of 10%, particularly an upper limit of 15.0%, more particularly an upper limit of 30.0%.

According to embodiments which can be combined with other embodiments described herein, the content of water vapor in the second processing gas atmosphere may be from a range between a lower limit of 0.0%, particularly a lower limit of 2.0%, more particularly a lower limit of 4.0%, and an upper limit of 6.0%, particularly an upper limit of 8.0%, more particularly an upper limit of 20.0%.

It is to be understood that according to embodiments described herein in which the second processing gas atmosphere includes water vapor, H₂, inert gas and O₂ the respective contents of water vapor, H₂, inert gas and O₂ may add up to 100% of the processing gas atmosphere.

According to embodiments which can be combined with other embodiments described herein, all constituent gases of the second processing gas atmosphere may be mixed prior to filling the vacuum chamber with the second processing gas atmosphere.

Accordingly, during deposition of the second layer in the second processing gas atmosphere all constituent gases of the second processing gas atmosphere may flow through the same gas showers. In particular, depending on the selected composition of the second processing gas atmosphere as described herein, H_{2,} water vapor, O₂ and inert gas may be supplied to the vacuum chamber through the same gas showers, e.g. the gas shower 135 as schematically shown in FIGS. 1 to 3. For example, the gaseous constituents of a selected second processing gas atmosphere may be mixed in the gas showers before the gaseous constituents of the selected second processing gas are provided into the vacuum chamber. Accordingly, a very homogenous second processing gas atmosphere can be established in the vacuum chamber.

According to embodiments which can be combined with other embodiments described herein, the second total pressure of the second processing gas atmosphere may be from 0.08 Pa to 3.0 Pa. In particular, the second total pressure of the second processing gas atmosphere may be lower than the first total pressure of the first processing gas atmosphere. The second total pressure of the second processing gas atmosphere can be from a range between a lower limit of 0.2 Pa, particularly a lower limit of 0.3 Pa, more particularly a lower limit of 0.4 Pa, and an upper limit of 0.6 Pa, particularly an upper limit of 0.7 Pa, more particularly an upper limit of 0.8 Pa. In particular, the total pressure of the second processing gas atmosphere may be 0.3 Pa. By sputtering the second layer, for example of a layer stack, from an indium oxide containing target in a processing gas atmosphere in which the second total pressure of the second processing gas atmosphere has been selected to be lower than the first total pressure of the first processing gas atmosphere, the crystallinity of the second layer, particularly the crystallinity of a layer stack including the second layer, may be adjusted. In particular, the crystallinity of the second layer can, for example, be controlled by the second total pressure in the second processing gas atmosphere. Particularly, by decreasing the second total pressure of the second processing gas atmosphere, the degree of crystallinity in the second layer, for example of a layer stack, may be increased.

According to embodiments which can be combined with other embodiments described herein, the second power supplied to the indium oxide containing target for sputtering the second layer may be higher than the first power supplied to the indium oxide containing target for sputtering the first layer. The second power supplied to the indium oxide containing target may be from a range between a lower limit of 5 kW, particularly a lower limit of 8 kW, more particularly a lower limit of 10 kW, and an upper limit of 13 kW, particularly an upper limit of 16 kW, more particularly an upper limit of 20 kW.

For example, in case of using a Gen 8.5 target having a target length of 2.7 m, the target may be provided with a power from a range between of 1.9 kW/m and 7.4 kW/m. According to further embodiments which can be combined with other embodiments described herein, the second power supplied to the indium oxide containing target may be normalized with respect to the substrate size. For example, the substrate size may be 5.5 m². Accordingly, it is to be understood that that respective lower limits and upper limits of the second power supplied to the target may be normalized with respect to the length of the target and/or the substrate size. By sputtering the second layer, for example of a layer stack, from an indium oxide containing target with a second power which has been selected from a lower limit to an upper limit as described herein, the crystallinity of the second layer, particularly the crystallinity of a layer stack including the second layer, may be adjusted. In particular, the crystallinity of the second layer or of a layer stack including the second layer can, for example, be controlled by the second power supplied to the indium oxide containing target. Particularly, by increasing the second power supplied to the indium oxide containing target, the degree of crystallinity in the second layer, for example of the layer stack may be increased.

According to embodiments which can be combined with other embodiments described herein, the first processing gas atmosphere includes water vapor, H₂, O₂ and an inert gas. It is to be understood that the content of the constituents of the first processing gas atmosphere according to embodiments described herein may add up to 100%. In particular, according to some embodiments which can be combined with other embodiments described herein, the content of water vapor, H₂, O₂ and inert gas may add up to 100% of the first processing gas atmosphere. The inert gas may be selected from the group consisting of helium, neon, argon, krypton, xenon or radon. In particular the inert gas may be argon (Ar).

According to embodiments which can be combined with other embodiments described herein, the partial pressure of water vapor in the first processing gas atmosphere may be from a range between a lower limit of 0.0 Pa, for example in a case in which the lower limit of the water vapor content of 0.0% has been selected for a first processing gas atmosphere or a second processing gas atmosphere, and an upper limit of 0.16 Pa, for example in a case in which the upper limit of the water vapor content of 20.0% has been selected for a first processing gas atmosphere with the upper limit of the total pressure of 0.8 Pa.

Accordingly, it will be understood that the partial pressure of water vapor in the processing gas atmosphere can be calculated by the product of the selected water vapor content in per cent [%] of the processing gas atmosphere and the selected total pressure of the processing gas atmosphere in Pascal [Pa]. Accordingly, depending on the selected values of the upper and lower limits of water vapor content in the processing gas atmosphere and the selected values of the upper and lower limits of the total pressure of the processing gas atmosphere corresponding values for the lower and the upper limit of the partial pressure of water vapor in the processing gas atmosphere can be calculated and selected.

According to embodiments which can be combined with other embodiments described herein, the partial pressure of H₂ in the first processing gas atmosphere may be from a range between a lower limit of 0.0044 Pa, for example in a case in which the lower limit of the H₂ content of 2.2% has been selected for a first processing gas atmosphere with the lower limit of the total pressure of 0.2 Pa, and an upper limit of 0.24 Pa, for example in a case in which the upper limit of the H₂ content of 30.0% has been selected for a first processing gas atmosphere with the upper limit of the total pressure of 0.8 Pa.

Accordingly, it will be understood that the partial pressure of H₂ in the processing gas atmosphere can be calculated by the product of the selected H₂ content in per cent [%] of the processing gas atmosphere and the selected total pressure of the processing gas atmosphere in Pascal [Pa]. Accordingly, depending on the selected values of the upper and lower limits of H₂ content in the processing gas atmosphere and the selected values of the upper and lower limits of the total pressure of the processing gas atmosphere, corresponding values for the lower and upper limit of the partial pressure of H₂ in the processing gas atmosphere can be calculated and selected.

According to embodiments which can be combined with other embodiments described herein, the second processing gas atmosphere includes water vapor, H₂, O₂ and an inert gas. It is to be understood that the content of the constituents of the second processing gas atmosphere according to embodiments described herein may add up to 100%. In particular, according to some embodiments which can be combined with other embodiments described herein, the content of water vapor, H₂, O₂ and inert gas may add up to 100% of the second processing gas atmosphere. The inert gas may be selected from the group consisting of helium, neon, argon, krypton, xenon or radon. In particular the inert gas may be argon (Ar). The contents and partial pressures of water vapor and H₂ in the second processing gas atmosphere may be selected within the ranges as specified herein by the respective upper and lower limits for the first processing gas atmosphere.

According to embodiments which can be combined with other embodiments described herein, the partial pressure of O₂ in the processing gas atmosphere may be from a range between a lower limit of 0.001 Pa, for example in a case in which the lower limit of the O₂ content of 0.5% has been selected for a processing gas atmosphere with the lower limit of the total pressure of 0.2 Pa, and an upper limit of 0.24 Pa, for example in a case in which the upper limit of the O₂ content of 30.0% has been selected for a processing gas atmosphere with the upper limit of the total pressure of 0.8 Pa.

Accordingly, it will be understood that the partial pressure of O₂ in the processing gas atmosphere can be calculated by the product of the selected O₂ content in per cent [%] of the processing gas atmosphere and the selected total pressure of the processing gas atmosphere in Pascal [Pa]. Accordingly, depending on the selected values of the upper and lower limits of O₂ content in the processing gas atmosphere and the selected values of the upper and lower limits of the total pressure of the processing gas atmosphere corresponding values for the lower and upper limit of the partial pressure of O₂ in the processing gas atmosphere can be calculated and selected.

According to embodiments which can be combined with other embodiments described herein, the content of inert gas in the first processing gas atmosphere and/or the second processing gas atmosphere may be from a range between a lower limit of 45%, particularly a lower limit of 73%, more particularly a lower limit of 81%, and an upper limit of 87.5%, particularly an upper limit of 92.0%, more particularly an upper limit of 97.3%. By sputtering a transparent conductive oxide layer from an indium oxide containing target in a processing gas atmosphere in which the content of inert gas in the processing gas atmosphere has been selected from a range between a lower limit and an upper limit as described herein, the quality of the transparent conductive oxide layer can be ensured. In particular, by providing a processing gas atmosphere with inert gas as described herein, the risk of flammability and explosion of H₂ in the processing gas atmosphere can be reduced or even eliminated.

According to embodiments which can be combined with other embodiments described herein, the partial pressure of inert gas in the first processing gas atmosphere and/or the second processing gas atmosphere may be from a range between a lower limit of 0.04 Pa, for example in a case in which the lower limit of the inert gas content of 20%, the upper limit of the water vapor content of 20%, the upper limit of the H₂ content of 30%, and the upper limit of the O₂ content of 30.0% has been selected for a processing gas atmosphere with the lower limit of the total pressure of 0.2 Pa, and an upper limit of 0.7724 Pa, for example in a case in which the upper limit of the inert gas content of 97.3%, the lower limit of the water vapor content of 0.0%, the lower limit of the H₂ content of 2.2%, and the lower limit of the O₂ content of 0.0% have been selected for a processing gas atmosphere with the upper limit of the total pressure of 0.8 Pa.

Accordingly, it will be understood that the partial pressure of inert gas in the processing gas atmosphere can be calculated by the product of the selected inert gas content in per cent [%] of the processing gas atmosphere and the selected total pressure of the processing gas atmosphere in Pascal [Pa]. Accordingly, depending on the selected values of the upper and lower limits of inert gas content in the processing gas atmosphere and the selected values of the upper and lower limits of the total pressure of the processing gas atmosphere corresponding values for the lower and the upper limit of the partial pressure of inert gas in the processing gas atmosphere can be calculated and selected.

According to embodiments which can be combined with other embodiments described herein, the first processing atmosphere may be selected and controlled for controlling the etchability of a layer, e.g. a first layer of a layer stack, for example by controlling the degree of amorphous structure of the first layer, e.g. by controlling the content of water vapor and/or the content of H₂ in the first processing gas atmosphere. In particular, by increasing the content of water vapor and/or the content of H₂ in the first processing gas atmosphere, the degree of amorphous structure in the first layer may be increased. In particular, by increasing the content of H₂ in the first processing gas atmosphere the number of crystalline grains, particularly at the interface between the substrate and the first layer may be decreased. According to embodiments which can be combined with other embodiments described herein, the etchability of the layer stack may be improved by only controlling the content of H₂ in the first processing gas atmosphere. This may be beneficial for the adjustment of the resistivity of the layer stack properties, in particular since water vapor may also influence resistivity additionally to etchability of the layer stack.

According to embodiments which can be combined with other embodiments described herein, the second processing atmosphere may be selected and controlled for controlling the sheet resistance of a layer, e.g. a second layer of a layer stack, for example by controlling the content of O₂ in the second processing gas atmosphere during deposition of the second layer. In particular, for optimizing the sheet resistance of a layer, particularly a layer stack, with respect to low resistance after an annealing, the content of O₂ in the second processing gas atmosphere during layer deposition has to be selected from a range between a lower limit and an upper limit as described herein. According to embodiments, after layer deposition an annealing procedure may be performed, for example in a temperature range from 160° C. to 320° C.

According to embodiments which can be combined with other embodiments described herein, the resistivity after annealing of the layer stack, for example including a first layer and a second layer as described herein, may be from a range between a lower limit of 100 μOhm cm, particularly a lower limit of 120 μOhm cm, more particularly a lower limit of 150 μOhm cm, and an upper limit of 250 μOhm cm, particularly an upper limit of 275 μOhm cm, more particularly an upper limit of 400 μOhm cm. In particular, the resistivity after annealing of the layer stack may be approximately 230 μOhm cm.

According to embodiments which can be combined with other embodiments described herein, the resistivity of the layer stack may be determined by the second layer.

According to embodiments which can be combined with other embodiments described herein, the first processing gas atmosphere may consist of water vapor, H₂, an inert gas, and a residual gas. The content of water vapor, H₂, inert gas and residual gas in the first processing gas atmosphere consisting of water vapor, H₂, inert gas, and residual gas may be selected from a respective lower limit to a respective upper limit as described herein.

According to embodiments which can be combined with other embodiments described herein, the second processing gas atmosphere may consist of water vapor, H₂, an inert gas, O₂, and a residual gas. The content of water vapor, H₂, inert gas and O₂ in the second processing gas atmosphere consisting of water vapor, H₂, inert gas, and O₂ and a residual gas may be selected from a respective lower limit to a respective upper limit as described herein.

According to embodiments which can be combined with other embodiments described herein, the residual gas may be any impurity or any contaminant in the first processing gas atmosphere or second processing gas atmosphere. According to embodiments which can be combined with other embodiments described herein, the content of residual gas may be from 0.0% to 1.0% of the respective processing gas atmosphere. In particular, the content of residual gas may be 0.0% of the respective processing gas atmosphere. It is to be understood that the content of the constituents of the processing gas atmosphere according to embodiments described herein may add up to 100%.

According to embodiments which can be combined with other embodiments described herein, the method 400 of manufacturing at least one layer may include manufacturing a layer stack, for example for display manufacturing, wherein the method includes: depositing a layer stack onto a substrate by sputtering a first layer with a first set of processing parameters from an indium oxide containing target; and sputtering a second layer with a second set of processing parameters different from the first set of processing parameters onto the first layer from an indium oxide containing target, wherein the first set of processing parameters is adapted for high etchability of the layer stack, and wherein the second set of processing parameters is adapted for low resistance of the layer stack.

According to embodiments described herein, the expression “the first set of processing parameters is adapted for high etchability of the layer stack” may be understood in that the first set of processing parameters is adapted such that the molecular structure of the first layer sputtered under the sputter conditions specified by the first set of processing parameters is adapted for etching, e.g. chemical etching, particularly wet chemical etching. For example, the first set of processing parameters may be adapted such that the molecular structure of the first layer sputtered under the sputter conditions specified by the first set of processing parameters has a degree of amorphous structure which is beneficial for etching.

According to embodiments described herein, the expression “the first set of processing parameters is adapted for high etchability of the layer stack” may be understood in that the first set of processing parameters is adapted such that the etchability of the first layer of the layer stack is better than the etchability of the second layer of the layer stack which is sputtered under the sputter conditions specified by the second set of processing parameters. For example, the first set of processing parameters may be adapted such that the degree of amorphous structure in the first layer is higher than the degree of amorphous structure in the second layer. Accordingly the etchability of the first layer may influence the etchability of the layer stack.

According to embodiments described herein, the expression “the second set of processing parameters is adapted for low resistance of the layer stack” may be understood in that the second set of processing parameters is adapted such that the second layer of the layer stack which is sputtered under the sputter conditions specified by the second set of processing parameters has resistivity from a range between a lower limit of 100 μOhm cm, particularly a lower limit of 125 μOhm cm, more particularly a lower limit of 150 μOhm cm, and an upper limit of 200 μOhm cm, particularly an upper limit of 250 μOhm cm, more particularly an upper limit of 400 μOhm cm. Accordingly the sheet resistance of the second layer may influence the sheet resistance of the layer stack.

According to embodiments which can be combined with other embodiments described herein, the method of manufacturing a layer stack may include patterning the layer stack by etching.

According to embodiments which can be combined with other embodiments described herein, the first set of processing parameters includes at least one first parameter selected from the group consisting of: H2-content provided in a first processing gas atmosphere; content of water vapor provided in the first processing gas atmosphere; O₂-content provided in the first processing gas atmosphere; first total pressure of the first processing gas atmosphere; and a first power supplied to the indium oxide containing target.

According to embodiments which can be combined with other embodiments described herein, the H2-content provided in the first processing gas atmosphere is from 2.2% to 30.0%.

According to embodiments which can be combined with other embodiments described herein, the content of water vapor provided in the first processing gas atmosphere is from 0.0% to 20%.

According to embodiments which can be combined with other embodiments described herein, the first total pressure of the first processing gas atmosphere is from 0.08 Pa to 3.0 Pa.

According to embodiments which can be combined with other embodiments described herein, the first power supplied to the indium oxide containing target is from 0.4 kW/m to 5.6 kW/m.

According to embodiments which can be combined with other embodiments described herein, the second set of processing parameters includes at least one second parameter selected from the group consisting of: H₂-content provided in a second processing gas atmosphere; content of water vapor provided in the second processing gas atmosphere; O₂-content provided in the second processing gas atmosphere; second total pressure of the second processing gas atmosphere; and a second power supplied to the indium oxide containing target.

According to embodiments which can be combined with other embodiments described herein, the O₂-content provided in the second processing gas atmosphere is from 0.0% to 30.0%.

According to embodiments which can be combined with other embodiments described herein, the second total pressure of the second processing gas atmosphere is from 0.08 Pa to 3.0 Pa.

According to embodiments which can be combined with other embodiments described herein, the second power supplied to the indium oxide containing target is from 1.9 kW/m to 7.4 kW/m.

According to embodiments which can be combined with other embodiments described herein, the first layer has a thickness from 10 nm to 50 nm and the second layer has a thickness from 30 nm to 150 nm.

According to embodiments described herein, a layer or a layer stack manufactured by the method of manufacturing at least one layer according to embodiments described herein may be employed in an electronic device, particularly in an opto-electronic device. Accordingly, by providing an electronic device with a layer and/or a layer stack according to embodiments described herein, the quality of the electronic device can be improved. In particular, it will be understood by the skilled person that the method of manufacturing at least one layer and the apparatus therefore, in particular the apparatus for vacuum sputter deposition, according to embodiments described herein provide for high quality and low cost TFT display manufacturing.

1. Apparatus for vacuum sputter deposition, comprising:
a vacuum chamber;
three or more sputter cathodes within the vacuum chamber for sputtering material on a substrate;
a gas distribution system for providing a processing gas including H₂ to the vacuum chamber;
a vacuum system for providing a vacuum inside the vacuum chamber; and
a safety arrangement for reducing the risk of an oxy-hydrogen explosion, wherein the safety arrangement comprises a dilution gas feeding unit connected to the vacuum system for dilution of the H₂-content of the processing gas.

2. Apparatus according to claim 1, wherein the vacuum system has at least one vacuum pump and a pipe configured for connecting the vacuum pump to be in fluid communication with the vacuum chamber, wherein the dilution gas feeding unit is connected to the pipe between the vacuum chamber and the vacuum pump.

3. Apparatus according to claim 1, wherein the dilution gas feeding unit comprises a redundant dilution gas measurement system for providing a redundant dilution gas mass flow measurement of the dilution gas provided to the vacuum system.

4. Apparatus according to claim 3, wherein the redundant dilution gas measurement system is connected to the gas distribution system for providing a feedback control for controlling a dilution ratio of H₂/dilution gas in the vacuum system, wherein the dilution ratio of H₂/dilution gas is at least 1/5.

5. Apparatus according to claim 1, wherein the safety arrangement further comprises a pressure control unit arranged within the vacuum system for measuring the pressure inside the vacuum system, wherein the pressure control unit is connected to a redundant H₂-shutdown system of the gas distribution system for shutting down an H₂-supply when a critical pressure, particularly a critical pressure of 0.008 mbar, of the processing gas within the vacuum system is detected by the pressure control unit.

6. Apparatus according to claim 1, wherein the safety arrangement further comprises a redundant processing gas pressure measurement system arranged inside the vacuum chamber, wherein the processing gas pressure measurement system is connected to a redundant H₂-shutdown system for shutting down an H₂-supply when a critical pressure, particularly a critical pressure of 0.008 mbar, of the processing gas within the vacuum chamber is detected.

7. Apparatus according to claim 1, wherein the gas distribution system comprises a redundant H₂-mass flow measurement system for providing a redundant measurement of the H₂ mass flow provided to the vacuum chamber.

8. Apparatus according claim 7, wherein the redundant H₂-mass flow measurement system is arranged inside a housing comprising an exhaust gas line connecting the housing with an outside atmosphere, wherein the exhaust gas line is provided with a H₂-sensor for detecting an H₂-leakage.

9. Apparatus according to claim 8, wherein the H₂-sensor is connected with a redundant H₂-shutdown system for shutting down the H₂-supply when a critical H₂-leakage is detected by H₂-sensor.

10. Apparatus according claim 1, wherein the safety arrangement further comprises a redundant processing gas measurement system for measuring the composition of the processing gas inside the vacuum chamber, wherein the redundant processing gas measurement system is connected to a redundant H₂-shutdown system for shutting down an H₂-supply when a critical H₂-content of the processing gas, particularly a deviation from a preselected H₂-content by 1% or more, inside the vacuum chamber is detected.

11. Apparatus according to claim 1, wherein the redundant processing gas pressure measurement system is connected to a redundant O₂-shutdown system of an O₂-supply unit of the gas distribution system for shutting down the O₂-supply when a critical pressure, particularly a critical pressure of 0.008 mbar, of the processing gas within the vacuum chamber is detected.

12. Apparatus according to claim 10, wherein the redundant processing gas measurement system is connected a redundant O₂-shutdown system for shutting down the O₂-supply when a critical O₂-content of the processing gas, deviation from a preselected O₂-content by 1% or more, inside the vacuum chamber is detected.

13. Method for reducing the risk of an oxy-hydrogen explosion in a vacuum deposition apparatus, wherein during vacuum deposition a processing gas with an H₂-content of at least 2.2% is employed, the method comprising:
feeding a dilution gas to a vacuum system of the vacuum deposition apparatus; and
diluting the H₂-content in the vacuum system with a dilution ratio of H₂/dilution gas of at least 1/5.

14. Method according to claim 13, further comprising:
redundantly measuring at least one parameter selected form the group consisting of: an dilution gas mass flow provided to the vacuum system, a pressure of the processing gas within the vacuum chamber, and the H₂-content provided to the vacuum chamber; and
shutting down an H₂-supply when at least one parameter selected form the group consisting of: a critical pressure inside the vacuum chamber, a critical pressure inside the vacuum system, a critical H₂-content, and a non-sufficient dilution ratio of H₂/dilution gas in a vacuum system of the vacuum deposition apparatus is determined.

15. Method of manufacturing at least one layer, comprising:
sputtering a layer from a sputter material containing cathode onto to a substrate in a processing gas atmosphere within a vacuum chamber, wherein the substrate is at rest during sputtering, wherein the processing gas comprises H₂ with a content of H₂ from 2.2% to 30.0%; and
conducting a method for reducing the risk of an oxy-hydrogen explosion in a vacuum deposition apparatus,
wherein during vacuum deposition a processing gas with an H₂-content of at least 2.2% is employed, the method for reducing the risk of an oxy-hydrogen explosion comprising:
feeding a dilution gas to a vacuum system of the vacuum deposition apparatus, and
diluting the H₂-content in the vacuum system with a dilution ratio of H₂/dilution gas of at least 1/5.

16. Apparatus according to claim 5, wherein the critical pressure is a pressure of 0.008 mbar.

17. Apparatus according to claim 6, wherein the critical pressure is a pressure of 0.008 mbar.

18. Apparatus according to claim 1, wherein the safety arrangement further comprises a redundant processing gas measurement system for measuring the composition of the processing gas inside the vacuum chamber, wherein the redundant processing gas measurement system is connected to a redundant H₂-shutdown system for shutting down an H₂-supply when a deviation from a preselected H₂-content by 1% or more inside the vacuum chamber is detected.

19. Apparatus according to claim 1, wherein the redundant processing gas pressure measurement system is connected to a redundant O₂-shutdown system of an O₂-supply unit of the gas distribution system for shutting down the O₂-supply when a critical pressure of 0.008 mbar of the processing gas within the vacuum chamber is detected.

20. Apparatus according to claim 11, wherein the redundant processing gas measurement system is connected a redundant O₂-shutdown system for shutting down the O₂-supply when a critical O₂-content of the processing gas, deviation from a preselected O₂-content by 1% or more, inside the vacuum chamber is detected.
